(19) United States
(12) Patent Application Publication
(10) Pub. No.: US 2026/0040591 A1
(43) Pub. Date: Feb. 5, 2026

(54) MULTILAYER TRENCH CAPACITOR AND METHOD OF MAKING THE SAME

(71) Applicant: SANDISK TECHNOLOGIES LLC, ADDISON, TX (US)

(72) Inventors: Takumi NAGAI, Yokkaichi (JP); Shinya IWASA, Yokkaichi (JP); Eiichi FUJIKURA, Yokkaichi (JP)

(21) Appl. No.: 18/788,942

(22) Filed: Jul. 30, 2024

(51) Int. Cl. H01L 29/94; H01L 21/8234; H01L 27/06; H01L 29/66; H01L 29/78

(52) U.S. Cl. CPC H10D 1/665; H10D 1/047; H10D 84/0151; H10D 84/038; H10D 84/811; H10D 30/60

(57) ABSTRACT

A semiconductor structure includes a semiconductor substrate including a first trench and a second trench in an upper portion thereof, a trench isolation structure including a dielectric material and located in the first trench, and a capacitor including a doped substrate electrode layer located within the semiconductor substrate and underlying and laterally surrounding the second trench, and in-trench capacitor material assembly located within the second trench and including at least one primary electrode layer, at least one complementary electrode layer, and node dielectric layers. Each neighboring pair among the doped substrate electrode layer, the at least one primary electrode layer, and the at least one complementary electrode layer is spaced from each other by a respective one of the node dielectric layers.

### FIELD

The present disclosure relates generally to the field of semiconductor devices, and particularly to a multilayer trench capacitor and methods for manufacturing the same.

### BACKGROUND

A capacitor may include a capacitor dielectric layer, such as a silicon oxide layer, between opposing electrically conductive electrodes.

### SUMMARY

According to an aspect of the present disclosure, a semiconductor structure comprises: a semiconductor substrate including a first trench and a second trench in an upper portion thereof; a trench isolation structure comprising a dielectric fill material and located in the first trench; and a capacitor which comprises: a doped substrate electrode layer located within the semiconductor substrate and underlying and laterally surrounding the second trench; and an in-trench capacitor material assembly located within the second trench and comprising at least one primary electrode layer, at least one complementary electrode layer, and node dielectric layers, wherein each neighboring pair among the doped substrate electrode layer, the at least one primary electrode layer, and the at least one complementary electrode layer is spaced from each other by a respective one of the node dielectric layers.

According to another aspect of the present disclosure, a method of forming a semiconductor structure is provided, which comprises: forming a first trench and a second trench in an upper portion of a semiconductor substrate by performing an etch process that simultaneously removes a first portion and a second portion of the semiconductor substrate; forming a trench isolation structure comprising a first portion of a dielectric fill material in the first trench and forming a void within the second trench; and forming in-trench capacitor material assembly located within the second trench and comprising a doped substrate electrode layer, at least one primary electrode layer, at least one complementary electrode layer, and node dielectric layers, wherein each neighboring pair among the doped substrate electrode layer, the at least one primary electrode layer, and the at least one complementary electrode layer is spaced from each other by a respective one of the node dielectric layers.

### BRIEF DESCRIPTION OF THE DRAWINGS

FIG. 1A is a vertical cross-sectional view of an exemplary structure after formation of a patterned hard mask layer over a semiconductor substrate according to an embodiment of the present disclosure.

FIG. 1B is a top-down view of the exemplary structure of FIG. 1A. The vertical plane A-A′ is the cut plane of the vertical cross-sectional view of FIG. 1A.

FIG. 2A is a vertical cross-sectional view of the exemplary structure after formation of a first trench and a second trench according to an embodiment of the present disclosure.

FIG. 2B is a top-down view of the exemplary structure of FIG. 2A. The vertical plane A-A′ is the cut plane of the vertical cross-sectional view of FIG. 2A.

FIG. 3 is a vertical cross-sectional view of the exemplary structure after formation of a doped substrate electrode layer according to an embodiment of the present disclosure.

FIG. 4 is a vertical cross-sectional view of the exemplary structure after formation of a trench isolation structure and a sacrificial trench isolation structure according to an embodiment of the present disclosure.

FIG. 5 is a vertical cross-sectional view of the exemplary structure after removal of the sacrificial trench isolation structure according to an embodiment of the present disclosure.

FIG. 6 is a vertical cross-sectional view of the exemplary structure after deposition of an alternating sequence of node dielectric material layers and electrode material layers according to an embodiment of the present disclosure.

FIG. 7A is a vertical cross-sectional view of the exemplary structure after formation of an in-trench capacitor material assembly according to an embodiment of the present disclosure.

FIG. 7B is a top-down view of the exemplary structure of FIG. 7A. The vertical plane A-A′ is the cut plane of the vertical cross-sectional view of FIG. 7A.

FIG. 7C is a top-down view of a first alternative configuration of the exemplary structure after the processing steps of FIGS. 7A and 7B.

FIG. 7D is a top-down view of a second alternative configuration of the exemplary structure after the processing steps of FIGS. 7A and 7B.

FIG. 7E is a top-down view of a third alternative configuration of the exemplary structure after the processing steps of FIGS. 7A and 7B.

FIG. 8 is a vertical cross-sectional view of the exemplary structure after vertically recessing the trench isolation structure according to an embodiment of the present disclosure.

FIG. 9 is a vertical cross-sectional view of the exemplary structure after removal of the patterned hard mask layer and a sacrificial pad layer according to an embodiment of the present disclosure.

FIG. 10 is a vertical cross-sectional view of the exemplary structure after formation of a gate dielectric layer, a gate electrode, and a gate cap dielectric according to an embodiment of the present disclosure.

FIG. 11 is a vertical cross-sectional view of the exemplary structure after formation of a field effect transistor according to an embodiment of the present disclosure.

FIG. 12 is a vertical cross-sectional view of the exemplary structure after formation of a dielectric capping layer and a contact-level dielectric layer according to an embodiment of the present disclosure.

FIG. 13 is a vertical cross-sectional view of the exemplary structure after formation of contact via cavities according to an embodiment of the present disclosure.

FIG. 14 is a vertical cross-sectional view of the exemplary structure after formation of metal-semiconductor alloy regions according to an embodiment of the present disclosure.

FIG. 15A is a vertical cross-sectional view of the exemplary structure after formation of various contact via structures, a line-level dielectric layer, and metal lines according to an embodiment of the present disclosure.

FIG. 15B is a horizontal cross-sectional view of the exemplary structure along the horizontal plane B-B′ of FIG. 15A. The vertical plane A-A′ is the cut plane of the vertical cross-sectional view of FIG. 15A.

FIG. 15C is a horizontal cross-sectional view of a first alternative configuration of the exemplary structure after the processing steps of FIGS. 15A and 15B.

FIG. 15D is a horizontal cross-sectional view of a second alternative configuration of the exemplary structure after the processing steps of FIGS. 15A and 15B.

### DETAILED DESCRIPTION

Capacitance of a planar capacitor in a semiconductor circuit is limited by the area of a semiconductor die that is available for the planar capacitor. Embodiments of the present disclosure are directed to a multilayer trench capacitor and methods for manufacturing the same. Trench capacitors provide a higher capacitance without increasing the footprint of the capacitor. A capacitor trench can be formed concurrently with formation of an isolation trench that is employed for device isolation. The capacitor trench can be filled with an in-trench capacitor material assembly that includes at least one primary electrode layer, at least one complementary electrode layer, and node dielectric layers to provide a capacitor providing a higher capacitance per unit area than planar capacitors.

The drawings are not drawn to scale. Multiple instances of an element may be duplicated where a single instance of the element is illustrated, unless the absence of duplication of elements is expressly described or clearly indicated otherwise. Ordinals such as “first,” “second,” and “third” are employed merely to identify similar elements, and different ordinals may be employed across the specification and the claims of the instant disclosure. The same reference numerals refer to the same element or similar element. Unless otherwise indicated, elements having the same reference numerals are presumed to have the same composition. As used herein, a first element located “on” a second element can be located on the exterior side of a surface of the second element or on the interior side of the second element. As used herein, a first element is located “directly on” a second element if there exist a physical contact between a surface of the first element and a surface of the second element.

As used herein, a “layer” refers to a material portion including a region having a thickness. A layer may extend over the entirety of an underlying or overlying structure, or may have an extent less than the extent of an underlying or overlying structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, and/or may have one or more layer thereupon, thereabove, and/or therebelow.

As used herein, a “layer stack” refers to a stack of layers. As used herein, a “line” or a “line structure” refers to a layer that has a predominant direction of extension, i.e., having a direction along which the layer extends the most.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material”, “insulating material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material upon activation of electrical dopants therein, i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

As used herein, a “field effect transistor” refers to any semiconductor device having a semiconductor channel through which electrical current flows with a current density modulated by an external electrical field. As used herein, a “channel region” refers to a semiconductor region in which flow of charge carriers (e.g., electrons or holes) is affected by an applied electrical field. A “gate electrode” refers to an electrically conductive electrode which applies an electric field that controls charge carrier flow in the channel region by. A “source region” refers to a doped semiconductor region that supplies charge carriers (e.g., electrons or holes) that flow through the channel region. A “drain region” refers to a doped semiconductor region that receives the charge carriers supplied by the source region and that flow through the channel region. A “source/drain region” may be a source region or a drain region. An “active region” collectively refers to a source region, a drain region, and a channel region of a field effect transistor. A “source extension region” refers to a doped semiconductor region that is a portion of a source region and having a lesser dopant concentration than the rest of the source region. A “drain extension region” refers to a doped semiconductor region that is a portion of a drain region and having a lesser dopant concentration than the rest of the drain region. An “active region extension” refers to a source extension region or a drain extension region.

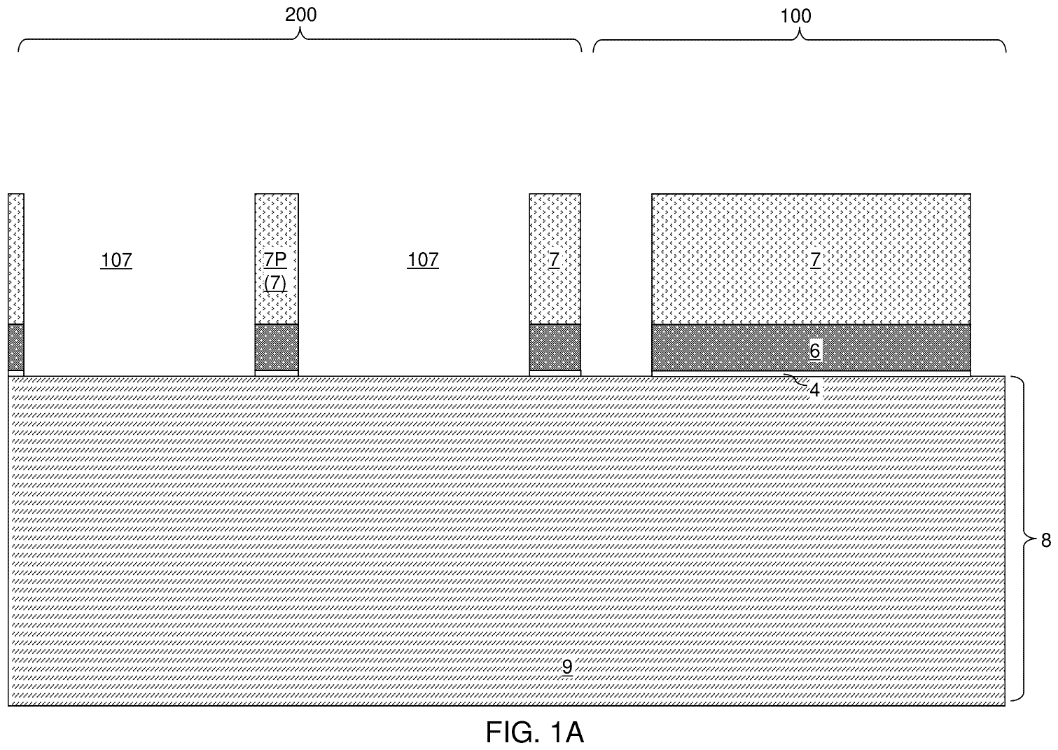

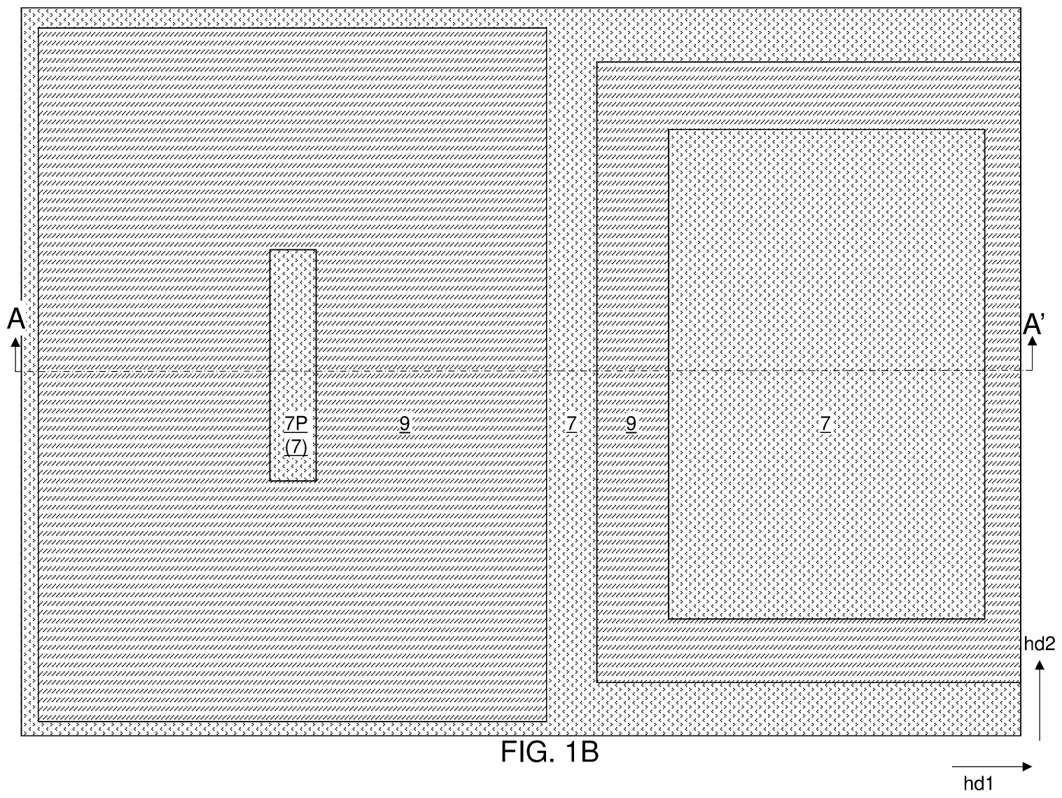

Referring to FIGS. 1A and 1B, an exemplary structure according to an embodiment of the present disclosure is illustrated. The exemplary structure includes a semiconductor substrate 8. As used herein, a “semiconductor substrate” refers to a substrate that includes at least one semiconductor material portion, i.e., at least one portion of a semiconductor material. The semiconductor substrate 8 includes a substrate semiconductor layer 9 at least at a top portion thereof. The semiconductor substrate 8 may optionally include at least one additional material layer at a bottom portion thereof. In one embodiment, the semiconductor substrate 8 can be a bulk semiconductor substrate consisting of a semiconductor material (e.g., single crystal silicon wafer), or can be a silicon-on-insulator (SOI) substrate including a buried insulator layer (such as a silicon oxide layer) underlying the semiconductor (e.g., silicon) material portion, and a handle substrate underlying the buried insulator layer.

In one embodiment, the substrate semiconductor layer 9 may include a lightly doped semiconductor material layer located on the semiconductor substrate 8. In another embodiment, the substrate semiconductor layer 9 may comprise an upper portion of the semiconductor substrate 8, such as a doped well in an upper portion of the silicon wafer. The substrate semiconductor layer 9 may include a lightly doped semiconductor material including electrical dopants of a first conductivity type at an atomic concentration in a range from 1.0×10¹⁴/cm³ to 1.0×10¹⁸/cm³, such as from 1.0×10¹⁵/cm³ to 1.0×10¹⁷/cm³, although lesser and greater atomic concentrations can also be employed. The first conductivity type may be p-type or n-type.

The semiconductor material of the substrate semiconductor layer 9 can be an elemental semiconductor material (such as silicon) or a compound semiconductor material (such as silicon-germanium, a III-V compound semiconductor material or a II-VI compound semiconductor material), or can be an organic semiconductor material. The thickness of the substrate semiconductor layer 9 can be in a range from 0.5 mm to 2 mm in case the semiconductor substrate 8 is a bulk semiconductor substrate. In the case the semiconductor substrate 8 is a semiconductor-on-insulator substrate, the thickness of the substrate semiconductor layer 9 may be in a range from 100 nm to 1,000 nm, although lesser and greater thicknesses can also be employed.

The exemplary structure comprises a capacitor region 200 in which a capacitor is subsequently formed, and may comprise a transistor region 100 in which a field effect transistor can be subsequently formed. At least one masked ion implantation process can be performed to implant electrical dopants into a surface portion of the substrate semiconductor layer 9 to form doped wells (not illustrated) in the transistor region 100. The doped wells may comprise p-doped wells and/or n-doped wells. For example, a double well structure or a triple well structure may be provided within an upper portion of the transistor region 100.

An optional pad dielectric layer 4 and a hard mask layer 6 may be formed over the top surface of the semiconductor substrate 8. The pad dielectric layer 4 may comprise a semiconductor oxide layer (such as silicon oxide layer) that is formed by oxidation of a surface portion of the semiconductor substrate 8. The thickness of the pad dielectric layer 4 may be in a range from 5 nm to 30 nm, although lesser and greater thicknesses may also be employed. The hard mask layer 6 comprises a hard mask material such as silicon nitride, silicon carbonitride, titanium nitride, etc. The thickness of the hard mask layer 6 may be in a range from 100 nm to 300 nm, such as from 120 nm to 250 nm, although lesser and greater thicknesses may also be employed.

A photoresist layer 7 can be applied over the hard mask layer 6, and can be lithographically patterned to form openings therein. The pattern of the openings in the photoresist layer 7 in the transistor region 100 includes a pattern of shallow trench isolation structures to be subsequently formed. The pattern of shallow trench isolation structures to be subsequently formed may be, for example, a pattern of the rectangular frame. The pattern of the openings in the photoresist layer in the capacitor region 200 includes a pattern of the perforated matrix, which is a pattern of the continuous opening 107 that laterally surrounds at least one discrete remaining portion of the photoresist layer 7. In one embodiment, an M×N rectangular array of discrete photoresist material portions 7P may be surrounded by a continuous opening in the photoresist layer. M may be an integer in a range from 1 to 10,000, and N may be an integer in a range from 1 to 10,000, although a greater number may also be employed for at least one of M and N. In the illustrated example in FIGS. 1A and 1B, M is 1 and Nis 1. The area of the continuous opening 107 defines the pattern of the perforated matrix. The areas of the M×N rectangular array of discrete photoresist material portions 7P can define the areas of the perforations in the perforated matrix. In other words, the area of the perforated matrix is defined by the area of the continuous perforated opening 107 in the photoresist layer 7. In one embodiment, the outer periphery of the continuous opening in the capacitor region 200 may have a pair of first sidewalls that are parallel to a first horizontal direction hd1 and a pair of second sidewalls that are parallel to a second horizontal direction hd2.

An anisotropic etch process can be performed to transfer the pattern of the openings in the photoresist layer 7 through the stack of the hard mask layer 6 and the pad dielectric layer 4. The pattern of the frame-shaped opening in the transistor region 100 defines the area in which a first trench is to be subsequently formed. The pattern of the perforated opening in the capacitor region 200 defines the area in which a second trench is to be subsequently formed. Portions of the hard mask layer 6 and the pad dielectric layer 4 that are not masked by the photoresist layer 7 can be removed by performing at least one anisotropic etch process. The at least one anisotropic etch process may comprise a first anisotropic etch process that etches the material of the hard mask layer 6 selective to the material of the pad dielectric layer 4, and the second anisotropic etch process that etches the material of the pad dielectric layer 4 selective to the material of the substrate semiconductor layer 9. The photoresist layer 7 can be subsequently removed, for example, by ashing.

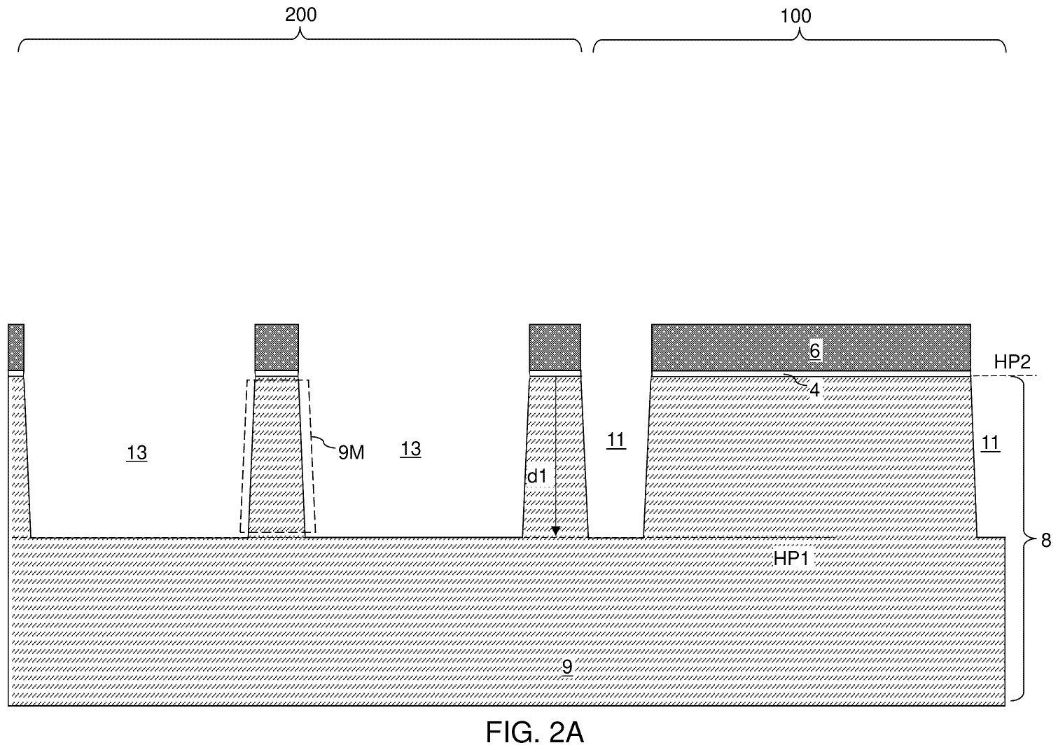

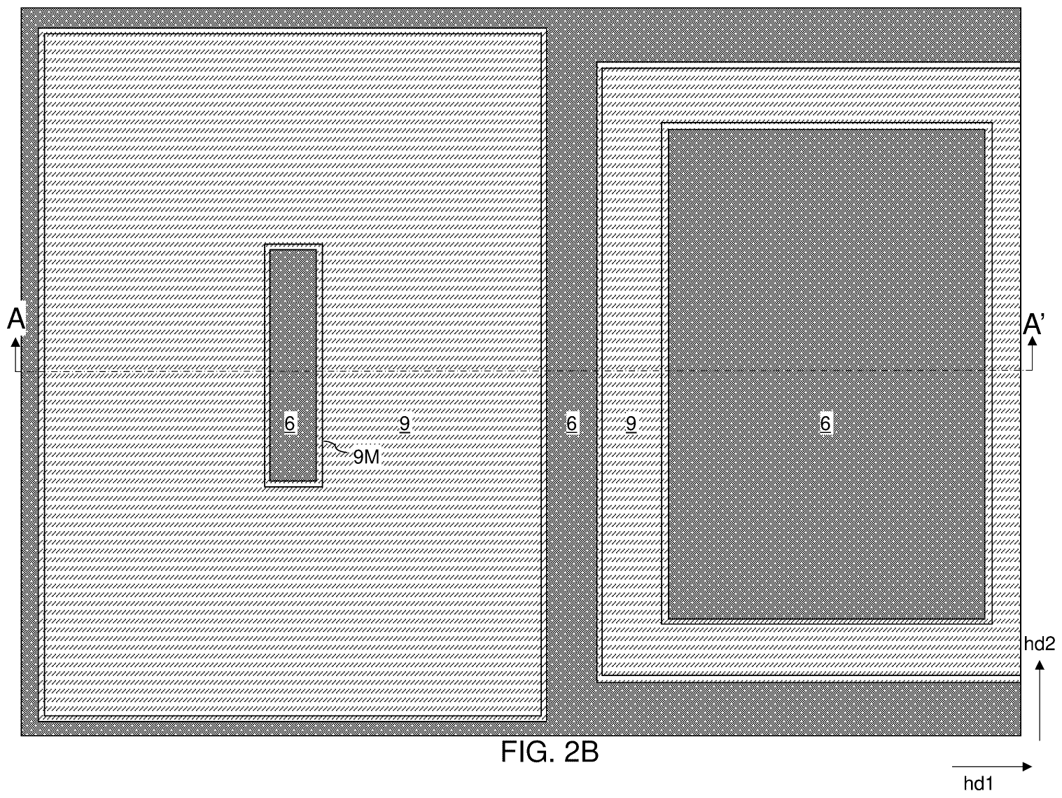

Referring to FIGS. 2A and 2B, an etch process can be performed to transfer the pattern of the openings in the patterned hard mask layer 6 into an upper portion of the substrate semiconductor layer 9. The etch process may comprise an anisotropic etch process that etches the semiconductor material of the substrate semiconductor layer 9 selective to the material of the hard mask layer 6. As used herein, an etch process etches a first material selective to a second material if the etch process removes the first material at a removal rate that is at least three times the removal rate of the second material. The anisotropic etch process may comprise a reactive etch process for etching the semiconductor material of the substrate semiconductor layer 9. The volumes of the cavities that are formed by removal of the upper portions of the substrate semiconductor layer 9 are herein referred to as trenches (11, 13), which comprises a first trench 11 formed in the transistor region 100 and a second trench 13 formed in the capacitor region 200. The first trench 11 may comprise a shallow trench that has the same pattern as that of the frame-shaped opening in the hard mask layer 6 in an upper portion of the substrate semiconductor layer 9 in the transistor region 100. The second trench 13 may comprise a shallow trench that has the same pattern as that of the continuous opening in the hard mask layer 6 which has a shape of a perforated continuous matrix in an upper portion of the substrate semiconductor layer 9 in the capacitor region 200.

The bottom surface of the second trench 13 may be formed in a first horizontal plane HP1. The vertical distance between the first horizontal plane HP1 and a second horizontal plane HP2 including the topmost surface of the substrate semiconductor layer 9 is herein referred to as a depth of the second trench 13, or as a first depth d1. The first depth d1 may be the same as the depth of the bottom surface of the first trench 11, or may be less than the depth of the bottom surface of the first trench 11 due to the pattern factor of the etch process that forms the first trench 11 and the second trench 13. A pattern factor refers to a phenomenon in an anisotropic etch process where the etch rate varies based on the density and size of the features being etched. This variation occurs because different areas of the mask may allow varying amounts of reactive ion or etchant penetration, leading to differential etch depths. As a result, smaller features or isolated features may etch at a higher etch rate compared to larger features or high-density features. Typically, the first trench 11 occupies a smaller fraction of the total area of the transistor region 100 compared to the fraction for the second trench 13 relative to the total area of the capacitor region 200. Thus, the first trench 11 may have the same depth as or may have a greater depth than the first depth d1 of the second trench 13. In one embodiment, the bottom surface of the second trench 13 can be formed within a first horizontal plane HP1 that is located at a depth that is in a range from 0.7 times the depth of a bottom surface of the first trench to 1.0 times the depth of the bottom surface of the first trench 11. In one embodiment, the bottom surface of the second trench 13 can be formed within a first horizontal plane HP1 that is located at a depth that is in a range from 0.9 times the depth of a bottom surface of the first trench to 1.0 times the depth of the bottom surface of the first trench 11.

Generally, the first trench 11 and the second trench 13 can be formed in an upper portion of a semiconductor substrate 8 by performing an etch process that simultaneously removes a first portion and a second portion of the semiconductor substrate 8. The etch process can be performed employing the patterned hard mask layer 6 as an etch mask for the etch process. The cavity from which the first portion is removed becomes the first trench 11, and the cavity from which the second portion is removed becomes the second trench 13. The area of the second trench 13 can be the same as the area of the opening in the hard mask layer 6, and thus, includes at least one perforation therethrough in a plan view. In one embodiment, the area of the second trench 13 in the plan view may include an M×N array of perforations.

The first depth d1 may be in a range from 150 nm to 400 nm, such as from 200 nm to 300 nm, although lesser and greater depths may also be employed. The taper angle of the sidewalls of the first trench 11 and the second trench 13 (as measured relative to the vertical direction) may be in a range from 0 degree to 6 degrees, such as from 0.5 degree to 3 degrees. Each unetched portion of the substrate semiconductor layer 9 is herein referred to as a mesa portion 9M of the substrate semiconductor layer 9, and is laterally surrounded by the second trench 13. Generally, at least one mesa portion 9M of the substrate semiconductor layer 9 can be laterally surrounded by the second trench 13. In one embodiment, an M×N array of mesa portions 9M of the substrate semiconductor layer 9 may be surrounded by the second trench 13, in which M can be a first integer in a range from 1 to 10,000, and N can be a second integer in a range from 1 to 10,000. The lateral dimension of each mesa portion 9M of the substrate semiconductor layer 9 along the first horizontal direction hd1 may be in a range from 100 nm to 1,000 nm, and the lateral dimension of each mesa portion 9M of the substrate semiconductor layer 9 along the second horizontal direction hd2 may be in a range from 100 nm to 1,000 nm, although lesser and greater dimensions may also be employed.

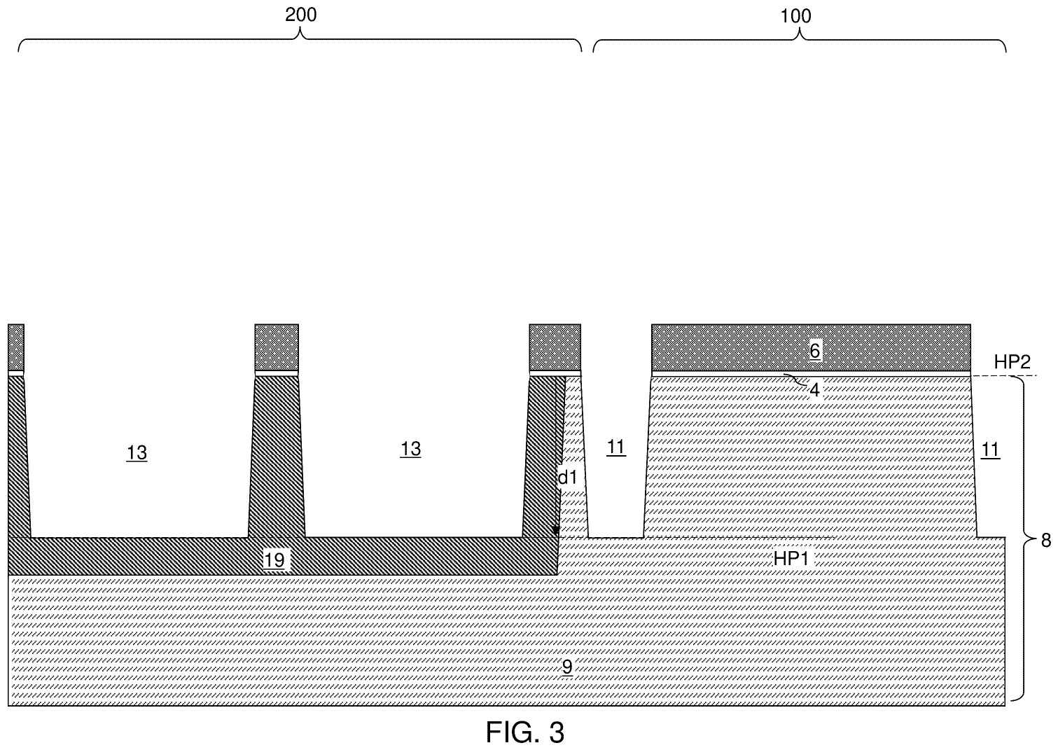

Referring to FIG. 3, an optional ion implantation mask layer (such as a photoresist layer) can be applied over the exemplary structure, and can be lithographically patterned to cover the transistor region 100 without covering the capacitor region 200. An ion implantation process can optionally be performed to implant dopants into a surface portion of the substrate semiconductor layer 9 that underlies and/or is proximal to surfaces of the second trench 13. A continuous implanted portion of the substrate semiconductor layer 9, which includes the entirety of the mesa portions 9M, is converted into a doped substrate electrode layer 19. The doped substrate electrode layer 19 functions as an electrode of a capacitor upon completion of manufacture of the capacitor. The doped substrate electrode layer 19 is formed as a continuous material layer that underlies and laterally surrounds the second trench 13.

Alternatively, the doped substrate electrode layer 19 may be formed in the upper portion of the semiconductor substrate 8 as a doped well prior to the step shown in FIGS. 1A and 1B. The second trench 13 is then formed in the doped well, such that the remaining portion of the doped well comprises the doped substrate electrode layer 19.

In a non-limiting exemplary configuration, the doped substrate electrode layer 19 may be electrically connected to the substrate semiconductor layer 9. In one embodiment, the doped substrate electrode layer 19 includes electrical dopants of the first conductivity type at an atomic concentration in a range from 5×10¹⁹/cm³ to 2×10²¹/cm³, although lesser and greater atomic concentrations may also be employed. The thickness of a horizontally-extending portion of the doped substrate electrode layer 19 that underlies a horizontal bottom surface of the second trench 13 may be in a range from 50 nm to 500 nm, although lesser and greater thicknesses may also be employed. Generally, the doped substrate electrode layer 19 is formed within the semiconductor substrate 8, and underlies and laterally surrounds the second trench 13.

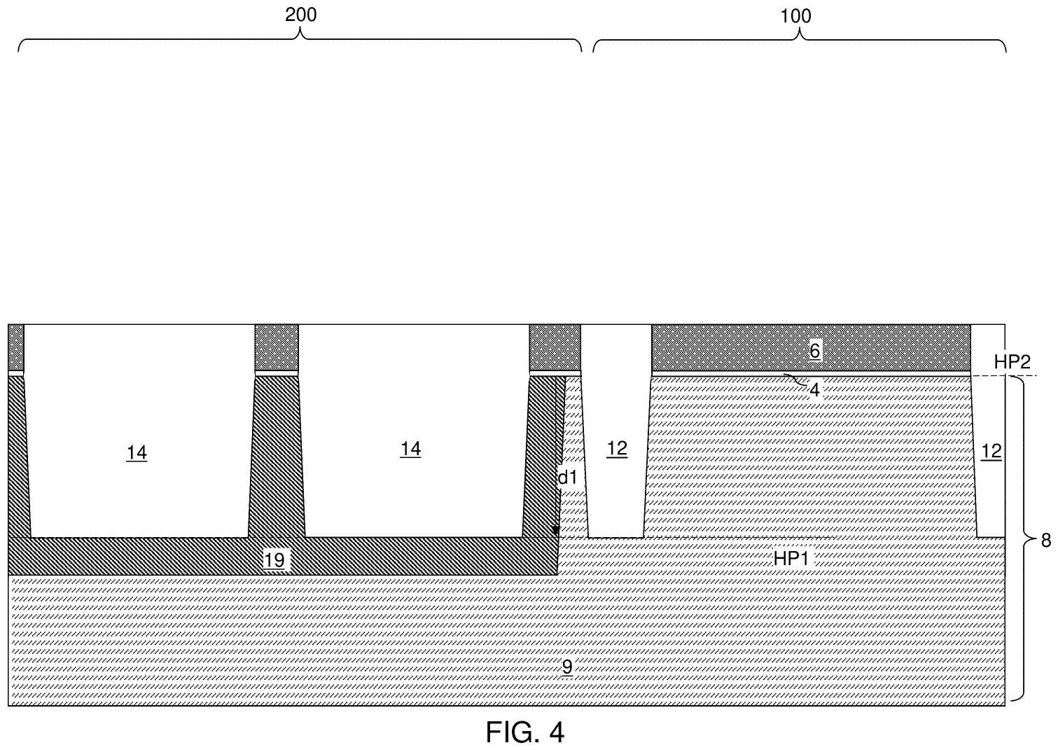

Referring to FIG. 4, a dielectric fill material, such as undoped silicate glass (i.e., silicon oxide) or a doped silicate glass, can be deposited in the first trench 11 and the second trench 13 by a conformal deposition process, such as a chemical vapor deposition process. Excess portions of the dielectric fill material can be removed from above the horizontal plane including the top surface of the hard mask layer 6 by performing a planarization process. The planarization process may comprise a recess etch process and/or a chemical mechanical polishing process. Generally, the dielectric fill material can be deposited in the first trench 11 and in the second trench 13, and can be subsequently planarized employing the patterned hard mask layer 6 as a planarization stopper layer. If the planarization process employs a recess etch process, the patterned hard mask layer 6 can be employed as an etch stop layer. If the planarization process employs a chemical mechanical polishing process, the patterned hard mask layer 6 can be employed as a polishing stopper layer. A remaining portion of the dielectric fill material that fills the first trench 11 and an overlying opening in the patterned hard mask layer 6 comprises a trench isolation structure 12, or a first trench isolation structure (e.g., a first shallow trench isolation structure). A remaining portion of the dielectric fill material that fills the second trench 13 and an overlying opening in the patterned hard mask layer 6 comprises a sacrificial trench isolation structure 14, or a second trench isolation structure (e.g., a second shallow trench isolation structure).

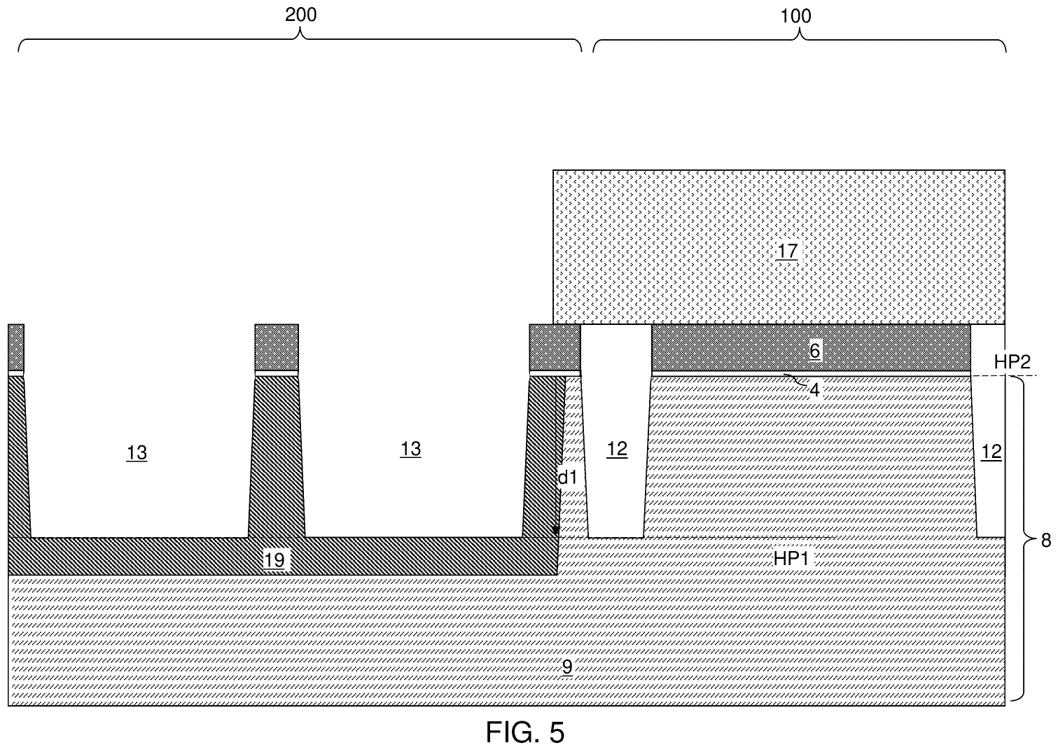

Referring to FIG. 5, a photoresist layer 17 can be applied over the exemplary structure illustrated in FIG. 4, and can be lithographically patterned to cover the transistor region 100 without covering the capacitor region 200. An etch process can be performed to etch the sacrificial trench isolation structure 14 selective to the materials of the doped substrate electrode layer 19 and the hard mask layer 6. The etch process may comprise an anisotropic etch process (such as a reactive ion etch process), an isotropic etch process (such as a wet etch process), or a combination thereof. The patterned hard mask layer 6 can be employed as an etch mask for the etch process that removes the sacrificial trench isolation structure 14 which includes a second portion of the dielectric fill material that is deposited in the second trench 13. Thus, the second portion of the dielectric fill material that is deposited in the second trench 13 can be removed without removing the first portion of the dielectric fill material from inside the second trench 13 (which is the trench isolation structure 12). The second trench 13 is reopened upon removal of the sacrificial trench isolation structure. Generally, a trench isolation structure 12 comprising a first portion of a dielectric fill material can be formed in the first trench 11, and a void can be provided within the second trench 13. The photoresist layer 17 can be subsequently removed, for example, by ashing.

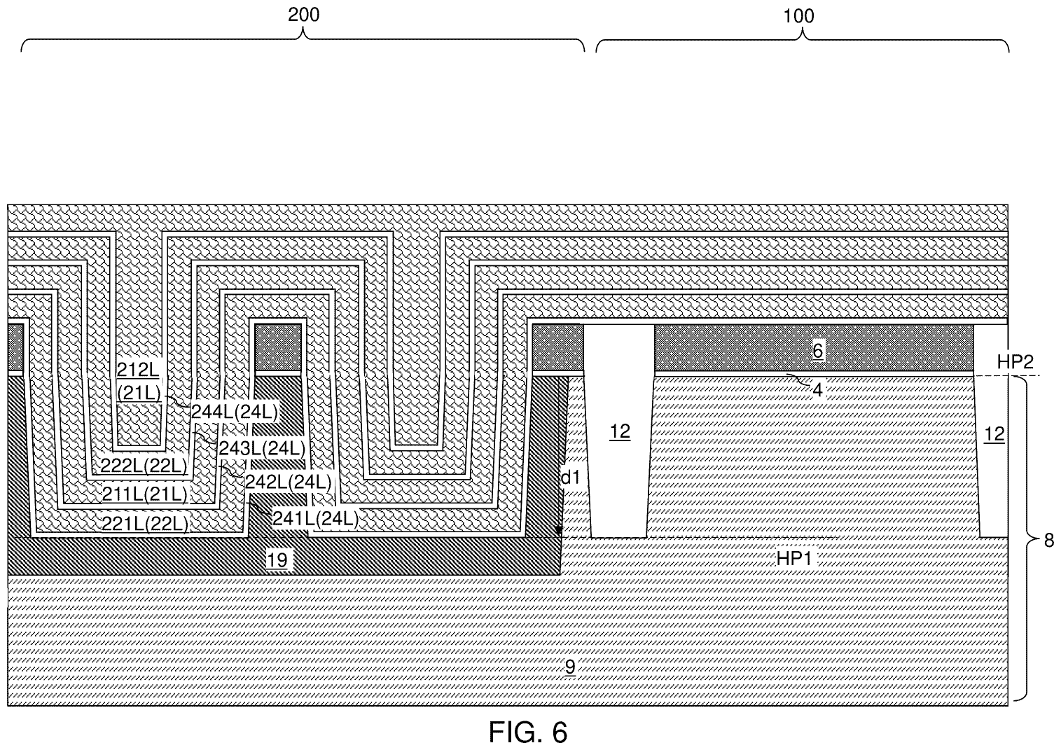

Referring to FIG. 6, an alternating sequence (21L, 22L, 24L) of node dielectric material layers 24L and electrode material layers (21L, 22L) can be deposited in the second trench 13 and over the hard mask layer 6. The node dielectric material layers 24L comprise a first node dielectric material layer 241L and a second node dielectric material layer 242L, and may optionally comprise one or more additional node dielectric material layers such as a third node dielectric material layer 243L, a fourth node dielectric material layer 244L, etc. In other words, at least two node dielectric layers 241L and 242L are formed in the second trench 13. The electrode material layers (21L, 22L) comprise at least two electrode material layers (21L, 22L). Upon sequentially numbering the electrode material layers (21L, 22L) in the order of deposition with consecutive positive integers starting with 1, each odd-numbered electrode material layer is herein referred to as a complementary electrode material layer 22L, and each even-numbered electrode material layer is herein referred to as a primary electrode material layer 21L.

The total number N of the electrode material layers (21L, 22L) may be in a range from 2 to 20, such as from 3 to 12, and/or from 4 to 8, although lesser and greater numbers may also be employed. The total number of the node dielectric material layers 24L may be the same as the total number of the electrode material layers (21L, 22L). The complementary electrode material layer(s) 22L and the primary electrode material layer(s) 21L alternate among the electrode material layers (21L, 22L) within the alternating sequence (21L, 22L, 24L) of node dielectric material layers 24L and electrode material layers (21L, 22L). If the total number of the electrode material layers (21L, 22L) is N, the total number of the complementary electrode material layers 22L is the largest integer that is not greater than (N+1)/2, and the total number of the primary electrode material layer 21L is the largest integer that is not greater than N/2. Generally, the electrode material layers (21L, 22L) comprise at least one complementary electrode material layer 22L and at least one primary electrode material layer 21L.

In one embodiment, each of the node dielectric material layers 24L may have the same material composition and the same thickness. For example, the node dielectric material layers 24L may comprise silicon oxide having a dielectric constant of 7.9 and/or a dielectric metal oxide material having a dielectric constant greater than 7.9. The thickness of the node dielectric material layer 24L may be in a range from 5 nm to 20 nm, although lesser and greater thicknesses may also be employed.

In one embodiment, one or more of the electrode material layers (21L, 22L) may comprise heavily-doped polycrystalline doped semiconductor layers that are electrically doped with p-type dopants or n-type dopants. The atomic concentration of electrical dopants within the heavily-doped polycrystalline doped semiconductor layers may be in a range from 5×10¹⁹/cm³ to 2×10²¹/cm³, although lesser and greater atomic concentrations may also be employed. Alternatively or additionally, one or more of the electrode material layers (21L, 22L) may comprise a metallic material, such as a conductive metallic nitride material (e.g., TiN, TaN, MON, and/or WN). The thickness of each electrode material layer (21L, 22L) may be in a range from 10 nm to 100 nm, such as from 20 nm to 60 nm, although lesser and greater thicknesses may also be employed. The thickness of each electrode material layer (21L, 22L) may be measured in a respective horizontally-extending portion such as a portion located in the transistor region 100.

The total thickness of the alternating sequence (21L, 22L, 24L) may be greater than the first depth d1, or may be greater than one half of a maximum lateral distance between a facing pair of sidewalls of the second trench 13. If the total thickness of the alternating sequence (21L, 22L, 24L) is greater than the first depth d1, but is less than one half of the maximum lateral distance between a facing pair of sidewalls of the second trench 13, a portion of the second trench 13 may be filled with a horizontally-extending portion of a topmost electrode material layer (21L or 22L), and a recessed surface of the topmost electrode material layer (21L or 22L) may overlie the second trench 13. If the total thickness of the alternating sequence (21L, 22L, 24L) is less than one half of the maximum lateral distance between a facing pair of sidewalls of the second trench 13, all seams in the topmost electrode material layer (21L or 22L) may be filled, and the topmost electrode material layer (21L or 22L) may have a planar horizontal top surface throughout, as illustrated in FIG. 6.

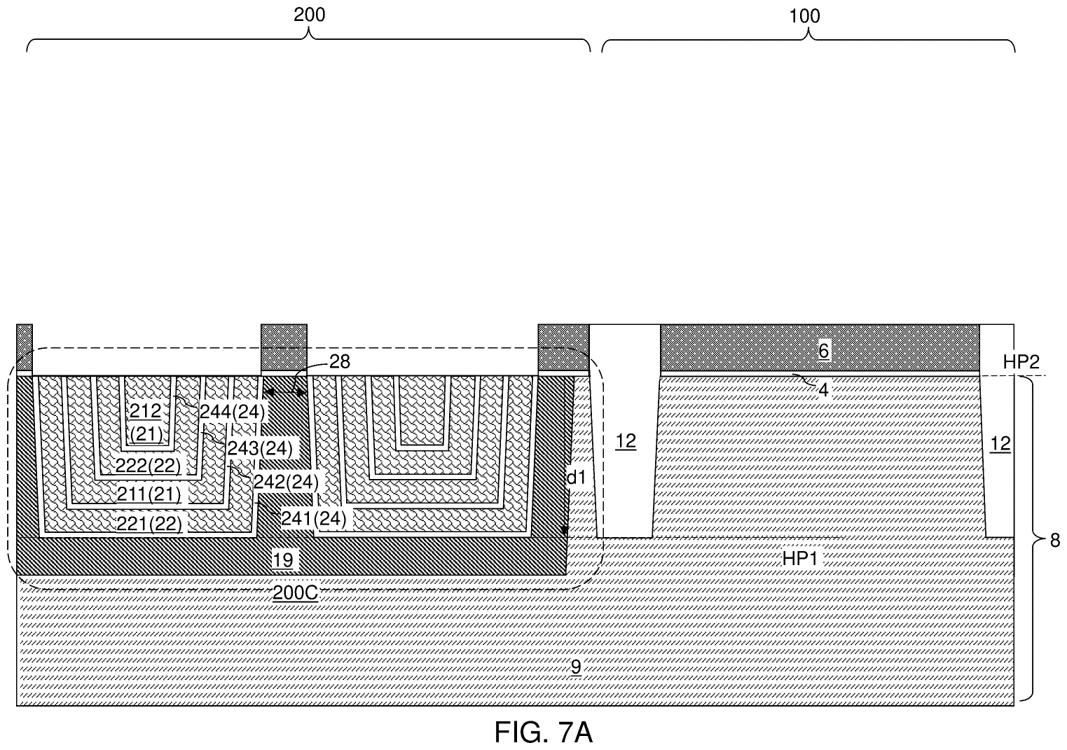

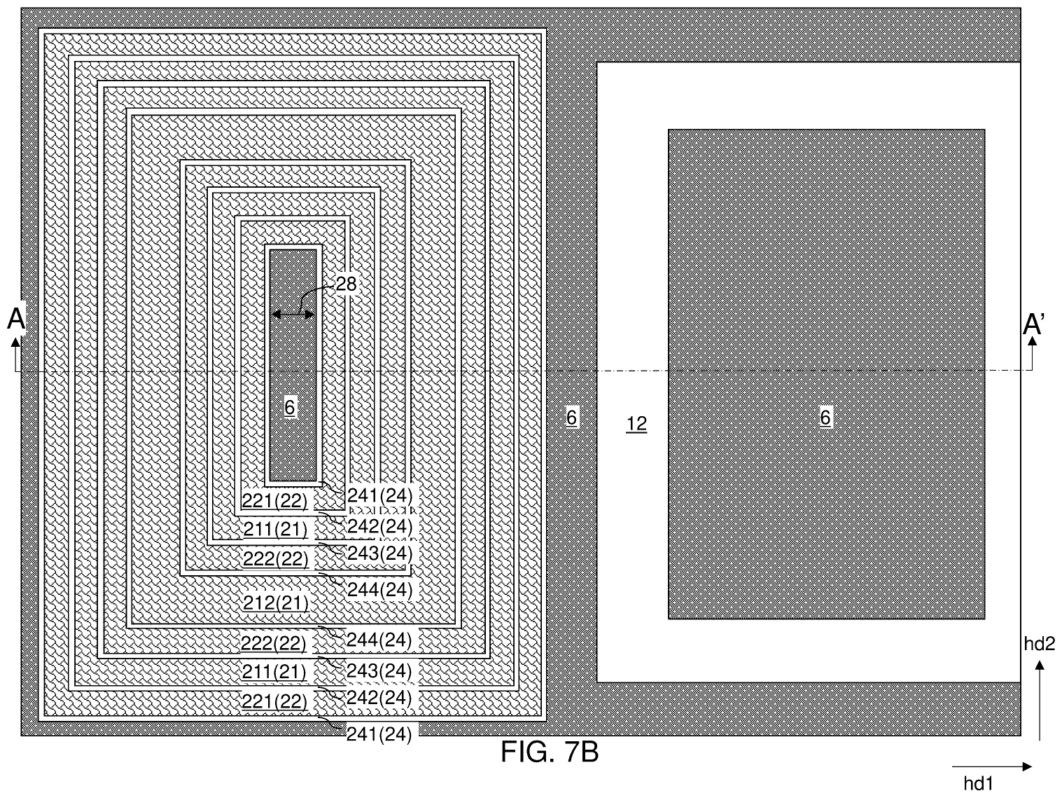

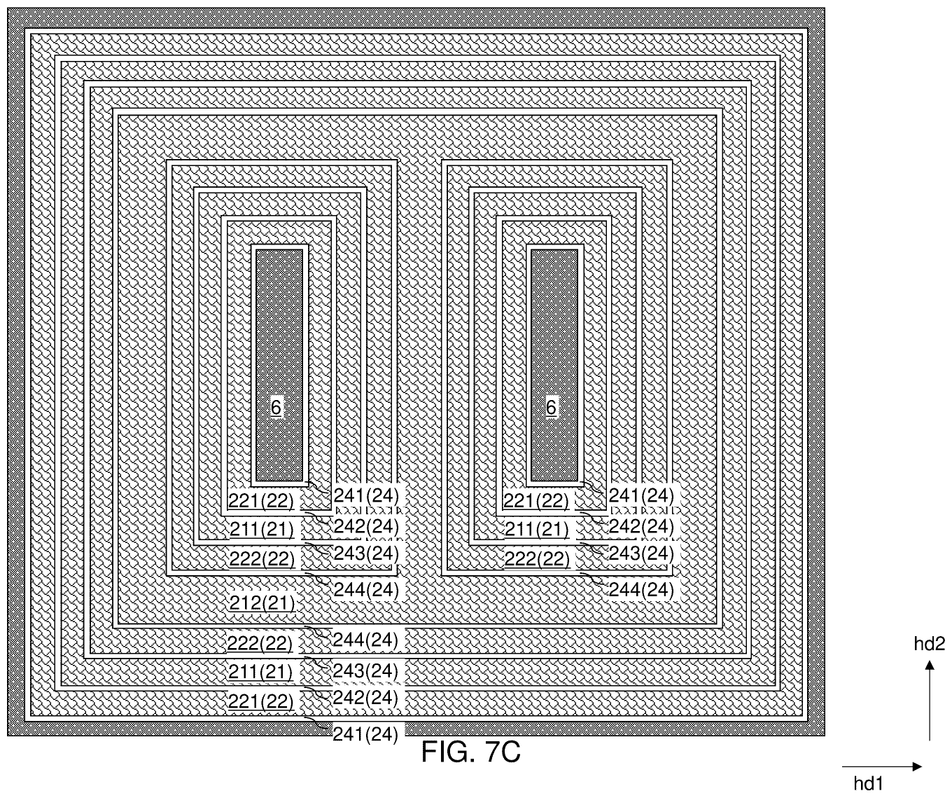

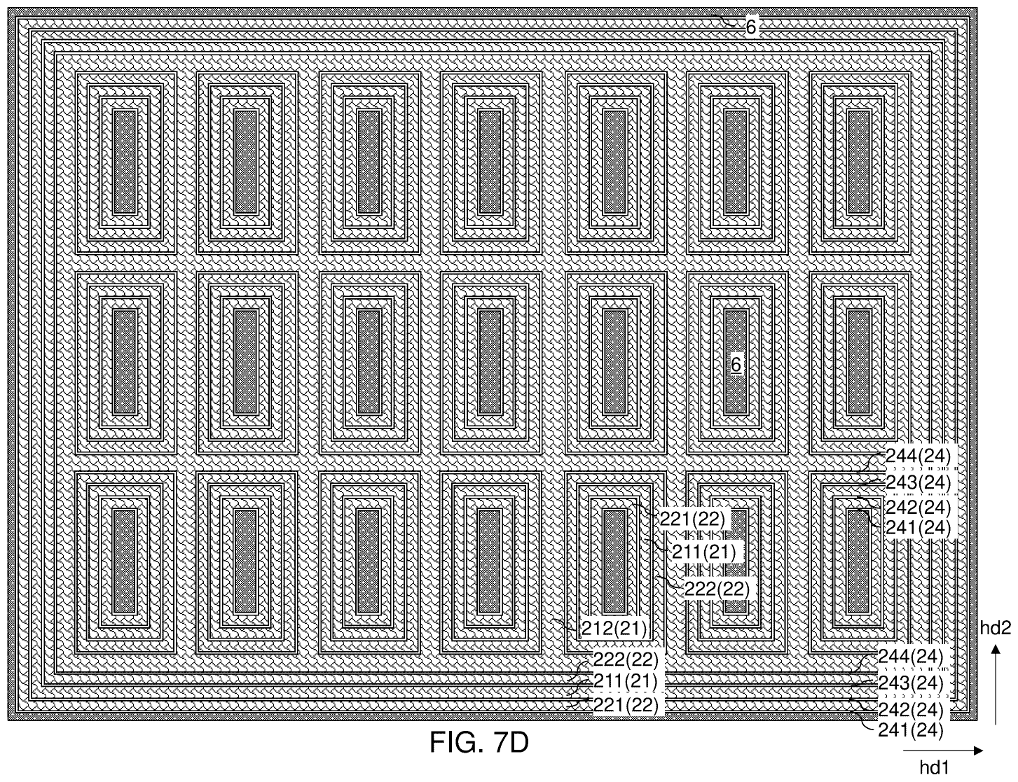

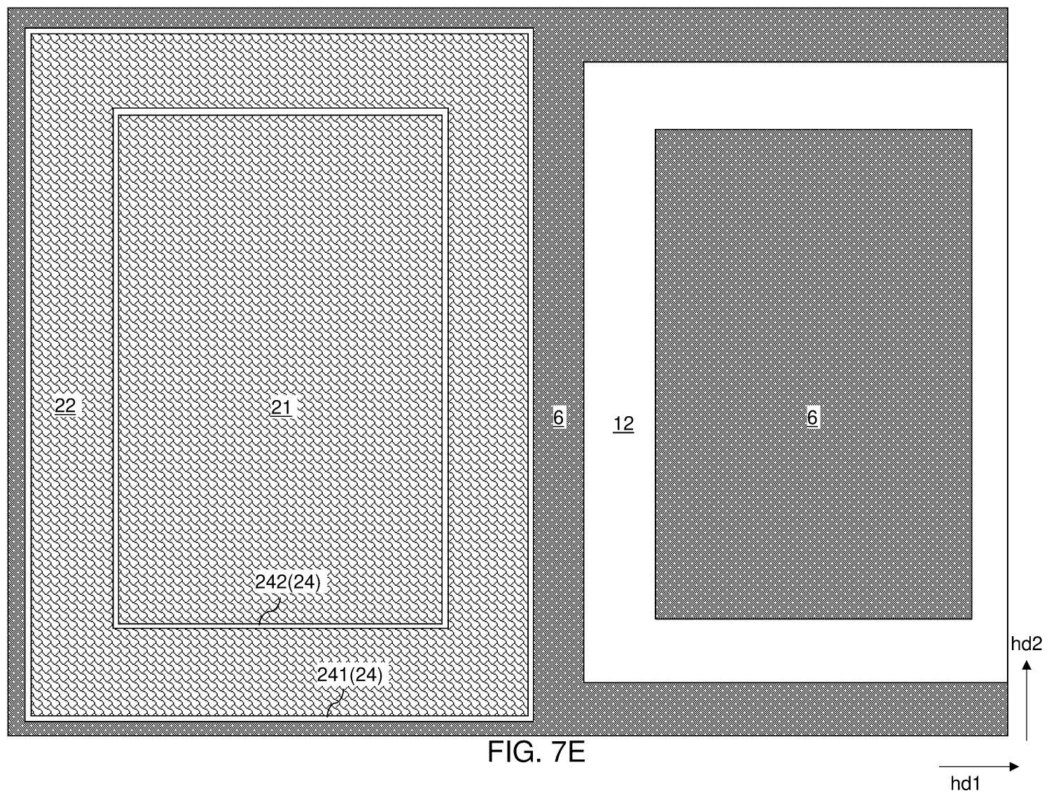

Referring to FIGS. 7A and 7B, a planarization process can be performed to remove the portion of the alternating sequence (21L, 22L, 24L) that overlies the horizontal plane including the top surface of the hard mask layer 6. The hard mask layer 6 can be employed as a planarization stopper layer during the planarization process. The planarization process may comprise a chemical mechanical polishing process and/or a selective recess etch process. If a chemical mechanical polishing process is employed for the planarization process, the materials of the alternating sequence (21L, 22L, 24L) can be polished from above the horizontal plane including the top surface of the hard mask layer 6 while the hard mask layer 6 is employed as a polishing stop layer. If a selective recess etch process for the planarization process, the materials of the alternating sequence (21L, 22L, 24L) can be simultaneously or alternately etched from above the horizontal plane including the top surface of the hard mask layer 6 while the hard mask layer 6 is employed as an etch stop layer.

Subsequently, a recess etch process can be performed to remove portions of the alternating sequence (21L, 22L, 24L) from above the second horizontal plane HP2 that includes the top surface of the substrate semiconductor layer 9. The recess etch process etches the materials of the electrode material layers (22L, 21L) and the node dielectric material layers 24L concurrently or alternately. The recess etch process may comprise at least one anisotropic etch step such, as at least one reactive ion etch step, and/or may comprise at least one isotropic etch step, such as at least one wet etch step. The set of remaining material portions of the alternating sequence (21L, 22L, 24L) after the recess etch process constitutes an in-trench capacitor material assembly (21, 22, 24), which is an assembly of material portions that are located within the second trench 13 and constitutes components of a capacitor.

Specifically, each remaining portion of a complementary electrode material layer 22L constitutes a complementary electrode layer 22; each remaining portion of a primary electrode material layer 21L constitutes a primary electrode layer 21; and each remaining portion of a node dielectric material layer 24L constitutes a node dielectric layer 24. The in-trench capacitor material assembly (21, 22, 24) is formed within the second trench 13, and comprises at least one primary electrode layer 21, at least one complementary electrode layer 22, and at least two node dielectric layers 24. Each neighboring pair among the doped substrate electrode layer 19, the at least one primary electrode layer 21, and the at least one complementary electrode layer 22 is spaced from each other by a respective one of the node dielectric layers 24.

The at least one primary electrode layer 21 comprises a first primary electrode layer 211, and may optionally comprise a second primary electrode layer 212 and/or a third primary electrode layer, etc. The at least one complementary electrode layer 22 comprises a first complementary electrode layer 221, and may optionally comprise a second complementary electrode layer 222 and/or a third complementary electrode layer, etc. The node dielectric layers 24 comprise, from bottom to top, a first node dielectric layer 241 and a second node dielectric layer 242, and may optionally comprise a third node dielectric layer 243, a fourth node dielectric layer 244, etc.

In one embodiment, the node dielectric layers 24 comprise a first node dielectric layer 241 in contact with the doped substrate electrode layer 19. The at least one complementary electrode layer 22 comprises a first complementary electrode layer 221 in contact with the first node dielectric layer 241. The node dielectric layers 24 further comprise a second node dielectric layer 242 in contact with the first complementary electrode layer 221. The at least one primary electrode layer 21 comprises a first primary electrode layer 211 in contact with the second node dielectric layer 242. In one embodiment, the node dielectric layers 24 also comprise a third node dielectric layer 243 in contact with the first primary electrode layer 211; and the at least one complementary electrode layer 22 also comprises a second complementary electrode layer 222 in contact with the third node dielectric layer 243.

In one embodiment, any of the at least one primary electrode layer 21 and the at least one complementary electrode layer 22 may comprise polycrystalline doped semiconductor layers. In another embodiment, any of the at least one primary electrode layer 21 and the at least one complementary electrode layer 22 may comprise metallic material layers.

In one embodiment, a bottom surface of the second trench 13 can be located within a first horizontal plane HP1 that is located at a depth that is in a range from 0.7 times a depth of a bottom surface of the first trench 11 to 1.0 times the depth of the bottom surface of the first trench 11. In one embodiment, a bottom surface of the first trench 11 and a bottom surface of the second trench 13 are located entirely within the first horizontal plane HP1. In one embodiment, a top surface of the doped substrate electrode layer 19 is located within a second horizontal plane HP2 including a top surface of the semiconductor substrate 8.

In one embodiment, the in-trench capacitor material assembly (21, 22, 24) comprises at least one opening therethrough in a plan view. In the illustrated example of FIGS. 7A and 7B, the in-trench capacitor material assembly (21, 22, 24) includes a rectangular opening 28 in the plan view. In one embodiment, each of the at least one opening is filled with a respective sub-portion of the doped substrate electrode layer 19. In one embodiment, each sub-portion of the doped substrate electrode layer 19 located within a respective opening in the in-trench capacitor material assembly (21, 22, 24) comprises a respective top surface segment that is located within a horizontal plane including a top surface of the semiconductor substrate 8.

Referring to FIGS. 7C and 7D, a first alternative configuration and a second alternative configuration of the exemplary structure are illustrated, respectively. In one embodiment, the at least one opening through the in-trench capacitor material assembly (21, 22, 24) may comprise a plurality of openings. In one embodiment, the at least one opening through the in-trench capacitor material assembly (21, 22, 24) may comprise an M×N array of rectangular openings in which M is a first integer in a range from 1 to 10,000, and N is a second integer from 1 to 10,000. FIG. 7C illustrates a configuration in which M is 2, and N is 1. FIG. 7D illustrates a configuration in which M is 7, and Nis 3. In one embodiment, the at least one opening comprises a plurality of openings. In one embodiment, the at least one opening comprises a two-dimensional array of openings arranged along a first horizontal direction hd1 and along a second horizontal direction hd2 that is different from the first horizontal direction hd1.

Referring to FIG. 7E, a third alternative configuration of the exemplary structure is illustrated. In this configuration, there are no openings in the in-trench capacitor material assembly (21, 22, 24). In this configuration, formation of the mesa portion 9M in the second trench 13 shown in FIGS. 2A and 2B is omitted.

Each of the node dielectric layers 24 comprises a respective horizontally-extending portion and a respective set of vertically-extending portions adjoined to the respective horizontally-extending portion. The area of the bottom surface of the horizontally-extending portion of each node dielectric layer 24 can be determined by the geometry of the second trench 13 and by the thicknesses of the various layers within the in-trench capacitor material assembly (21, 22, 24). The total area of the outer sidewalls of the vertically-extending portions of each node dielectric layer 24 can also be determined by the geometry of the second trench 13 and by the thicknesses of the various layers within the in-trench capacitor material assembly (21, 22, 24). The combination of the doped substrate electrode layer 19 and the in-trench capacitor material assembly (21, 22, 24) constitutes a capacitor 200C.

Table 1 below illustrates examples of the various geometrical parameters for four illustrative examples for the in-trench capacitor material assembly (21, 22, 24) for a first exemplary case in which all wall-to-wall distances between each facing pair of sidewalls of the second trench 13 separated by a respective void are the same as the first depth d1. The four illustrative examples include a first exemplary configuration including a single square-shaped opening within the in-trench capacitor material assembly (21, 22, 24), a second exemplary configuration including a 10×10 rectangular array of square-shaped openings within the in-trench capacitor material assembly (21, 22, 24), a third exemplary configuration including a 100×100 rectangular array of square-shaped openings within the in-trench capacitor material assembly (21, 22, 24), and a fourth exemplary configuration including a 1,000×1,000 rectangular array of square-shaped openings within the in-trench capacitor material assembly (21, 22, 24).

For the purpose of illustration, each square-shaped opening has sidewalls with a length of the first depth d1 (i.e., the depth of the second trench). A pair of first sidewalls of each square-shaped opening is parallel to a first horizontal direction hd1 (which is a first direction of repetition for each array of multiple openings), and a pair of second sidewalls of each square-shaped opening is parallel to a second horizontal direction hd2 (which is a second direction of repetition for each array of multiple openings). All sidewalls of the second trench 13 are assumed to be vertical. The lateral distance between each neighboring pair of sidewalls of the second trench 13 is assumed to equal the first depth d1. The sum of the thickness of a node dielectric layer 24 and the thickness of an electrode layer (21 or 22) is set at 0.125 times the first depth d1 for the purpose of the calculation. It should be understood that these assumptions are for the purpose of estimating various estimations for the areas of the bottom surfaces of the horizontally-extending portions of each node dielectric layer 24, and for the total areas of all outer sidewall surfaces of each node dielectric layer 24. Thus, by adjusting the various dimensional parameters and the taper angles of the sidewalls of the second trench isolation structures, and/or by selecting different numbers for the total number of openings in the in-trench capacitor material assembly (21, 22, 24), different values can be generated for the various numbers shown in Table 1.

TABLE 1
Characteristic dimensions for exemplary configurations of the capacitor of the present disclosure.

| | | a 10 × 10 | | |
|---|---|---|---|---|
| | a single | square | a 100 × 100 | a 1000 × 1000 |
| type of openings in an in-trench | square | array of | square array | square array |
| capacitor material assembly | opening | openings | of openings | of openings |
| total number of openings in a plan | 1 | 100 | 10,000 | 1,000,000 |
| view | | | | |
| depth of a capacitor trench | d1 | d1 | d1 | d1 |
| lateral distance between each | d1 | d1 | d1 | d1 |
| neighboring pair of sidewalls | | | | |
| length of outer sidewalls along a | (2 × 1 + | (2 × 10 + | (2 × 100 + | (2 × 1000 + |
| first horizontal direction hd1 | 1) × d1 = | 1) × d1 = | 1) × d1 = | 1) × d1 = |
| | 3 d1 | 21 d1 | 201 d1 | 2001 d1 |
| length of outer sidewalls along a | (2 × 1 + | (2 × 10 + | (2 × 100 + | (2 × 1000 + |
| second horizontal direction hd2 | 1) × d1 = | 1) × d1 = | 1) × d1 = | 1) × d1 = |
| | 3 d1 | 21 d1 | 201 d1 | 2001 d1 |
| total area enclosed by outer | 9 (d1)² | 441 (d1)2 | 40,401 (d1)² | 4,004,001 (d1)² |
| sidewalls | | | | |
| length of each sidewall of each | d1 | d1 | d1 | d1 |
| opening | | | | |
| total area of all openings | (d1)² | 100 (d1)² | 10,000 (d1)² | 1,000,000 (d1)² |
| total bottom area of the trench | 8 (d1)² | 341 (d1)² | 30,401 (d1)² | 3,004,001(d1)² |
| (=total area of a horizontal surface | | | | |
| of a first node dielectric layer) | | | | |
| total area of outer sidewalls | 4 × 3 | 4 × 21 d1 × | 4 × 201 d1 × | 4 x 2001 d1 x |
| | d1 × d1 = 12 (d1)² | d1 = | d1 = | d1 = |
| | | 84 (d1)² | 804 (d1)² | 8004 (d1)² |
| total area of sidewalls around | 1 × 4 × | 100 × 4 × | 10,000 × 4 × | 1,000,000 × 4 × |
| openings | d1 × d1 = 4 | d1 × d1 = | d1 × d1 = | d1 × d1 = |
| | (d1)² | 400 (d1)² | 40,000 (d1)² | 4,000,000 |
| | | | | (d1)² |
| total area of all types of sidewalls | 16 (d1)² | 484 (d1)² | 40,804 (d1)² | 4,008,004 (d1)² |
| of the trench (=total area of | | | | |
| vertical surfaces of a first node | | | | |
| dielectric layer) | | | | |
| sum of a thickness of a node | 0.125 d1 | 0.125 d1 | 0.125 d1 | 0.125 d1 |
| dielectric layer and a thickness of | | | | |
| a primary or complementary | | | | |
| electrode layer | | | | |
| total area of a horizontal bottom | (2.75 × | (20.75 × | (200.75 × | (2,000.5 × |
| surface of a second node dielectric | 2.75 − | 20.75 − | 200.75 − | 2,000.5 − |
| layer | 1.25 × | 100 × 1.25 × | 10,00 × 1.25 × | 1,000,000 × |
| | 1.25) × | 1.25) × | 1.25) × | 1.25 × 1.25) × |
| | (d1)² = | (d1)² = | (d1)² = | (d1)² = |
| | 6.0 (d1)² | 274.3125 (d1)² | 24,650.5625 (d1)² | 2,439,500.25 (d1)² |
| total area of a horizontal bottom | (2.5 × | (20.5 × | (200.5 × | (2,000.5 × |
| surface of a third node dielectric | 2.5 − | 20.5 − 100 | 200.5 − | 2,000.5 − |
| layer | 1.5 × | × 1.5 × 1.5) × | 10,00 × 1.5 × | 1,000,000 × |
| | 1.5) × | (d1)² = 195.25 | 1.5) × (d1)² = | 1.5 × 1.5)× |
| | (d1)² = 4 (d1)² | (d1)² | 17,700.25 (d1)² | (d1)² = |
| | | | | 1,752.000 (d1)² |
| total area of a horizontal bottom | (2.25 × | (20.25 × | (200.25 × | (2,000.25 × |
| surface of a third node dielectric | 2.25 − | 20.25 − | 200.25 − | 2,000.25 − |
| layer | 1.75 × | 100 × 1.75 × | 10,00 × 1.75 × | 1,000,000 × |
| | 1.75) × | 1.75) × | 1.75) × | 1.75 × 1.75) × |
| | (d1)² = 2 | (d1)² = | (d1)² = ~9,475 | (d1)² = ~938,500 |
| | (d1)² | 103.8125 (d1)² | (d1)² | (d1)² |
| total area of outer vertical surfaces | (4 × | (4 × 20.75 × | (4 × 200.75 × | (4 × 2,000.75 × |
| of a second node dielectric layer | 2.75 × | 0.875 + | 0.875 + | 0.875 + |
| | 0.875 + | 100 × 4 × | 10,000 × 4 × | 1,000,000 × 4 × |
| | 4 × | 1.25 × | 1.25 × | 1.25 × |
| | 1.25 × | 0.875) | 0.875) | 0.875) |
| | 0.875) | (d1)² = | (d1)² = ~44,452 | (d1)² = ~4,382,002 |
| | (d1)² = 14 (d1)² | 510.125 (d1)² | (d1)² | (d1)² |
| total area of outer vertical surfaces | (4 × 2.5 × | (4 × 20.5 × | (4 × 200.5 × | (4 × 2,000.5 × |
| of a third node dielectric layer | 0.75 + | 0.75 + 100 × | 0.75 + | 0.75 + |
| | 4 × | 4 × 1.5 × | 10,000 × 4 × | 1,000,000 × 4 × |
| | 1.5 × | 0.75) (d1)² = | 1.5 × 0.75) | 1.5 × 0.75) |
| | 0.75) | 511.5 (d1)² | (d1)² = | (d1)² = |
| | (d1)² = | | 45,601.5 (d1)² | 4,506,001.5 (d1)² |
| | 12 (d1)² | | | |
| total area of outer vertical surfaces | (4 × | (4 × 20.25 × | (4 × 200.25 × | (4 × 2,000.25 × |
| of a fourth node dielectric layer | 2.25 × | 0.625 + | 0.625 + | 0.625 + |
| | 0.625 + | 100 × 4 × | 10,000 × 4 × | 1,000,000 × 4 × |
| | 4 × | 1.75 × | 1.75 × | 1.75 × |
| | 1.75 × | 0.625) | 0.625) | 0.625) |
| | 0.625) | (d1)² = | (d1)² = ~44,250 | (d1)² = ~4,380,000 |
| | (d1)² = | 488.125 (d1)² | | (d1)² |
| | 10 (d1)² | | | |
| the ratio of a horizontal bottom | 1.0 | 1.0 | 1.0 | 1.0 |
| surface area of a first node | | | | |
| dielectric layer to the horizontal | | | | |
| bottom surface area of the first | | | | |
| node dielectric layer | | | | |
| the ratio of a horizontal bottom | 0.75 | 0.8044 | 0.8104 | 0.812 |
| surface area of a second node | | | | |
| dielectric layer to the horizontal | | | | |
| bottom surface area of the first | | | | |
| node dielectric layer | | | | |
| the ratio of a horizontal bottom | 0.5 | 0.5724 | 0.5819 | 0.5824 |
| surface area of a third node | | | | |
| dielectric layer to the horizontal | | | | |
| bottom surface area of the first | | | | |
| node dielectric layer | | | | |
| the ratio of a horizontal bottom | 0.25 | 0.3045 | 0.3116 | 0.3124 |
| surface area of a fourth node | | | | |
| dielectric layer to the horizontal | | | | |
| bottom surface area of the first | | | | |
| node dielectric layer | | | | |
| the ratio of the total outer vertical | 1.0 | 1.0 | 1.0 | 1.0 |
| surface area of a first node | | | | |
| dielectric layer to the total outer | | | | |
| vertical surface area of the first | | | | |
| node dielectric layer | | | | |
| the ratio of the total outer vertical | 0.875 | 1.0542 | 1.0894 | ~1.0933 |
| surface area of a second node | | | | |
| dielectric layer to the total outer | | | | |
| vertical surface area of the first | | | | |
| node dielectric layer | | | | |
| the ratio of the total outer vertical | 0.75 | 1.0568 | 1.0195 | ~1.1242 |
| surface area of a third node | | | | |
| dielectric layer to the total outer | | | | |
| vertical surface area of the first | | | | |
| node dielectric layer | | | | |
| the ratio of the total outer vertical | 0.625 | 1.0085 | 1.0845 | ~1.0928 |
| surface area of a fourth node | | | | |
| dielectric layer to the total outer | | | | |
| vertical surface area of the first | | | | |
| node dielectric layer | | | | |
| the ratio of a horizontal bottom | 0.5 | ~0.704 | 0.745 | ~0.749 |
| surface area to total outer vertical | | | | |
| surface area for a first node | | | | |
| dielectric layer | | | | |
| the ratio of a horizontal bottom | 0.4286 | 0.5376 | 0.554 | 0.5568 |
| surface area to total outer vertical | | | | |
| surface area for a second node | | | | |
| dielectric layer | | | | |
| the ratio of a horizontal bottom | 0.3333 | 0.3817 | 0.2078 | 0.3888 |
| surface area to total outer vertical | | | | |
| surface area for a third node | | | | |
| dielectric layer | | | | |
| the ratio of a horizontal bottom | 0.2 | 0.2127 | 0.2142 | 0.2143 |
| surface area to total outer vertical | | | | |
| surface area for a fourth node | | | | |
| dielectric layer | | | | |
| total node dielectric area = the sum | 72 (d1)² | 2,908.1250 (d1)² | 257,335.6250 (d1)² | 25,410,010.0625 (d1)² |
| of all horizontal bottom surface | | | | |
| areas and all outer vertical surface | | | | |
| areas for all 4 node dielectrics | | | | |
| device area (as defined by the | 9 (d1)² | 441 (d1)² | 40,401 (d1)² | 4,004,001 (d1)² |
| outer periphery of the second | | | | |
| trench) | | | | |
| the ratio of the total node dielectric | 8 | ~6.594 | ~6.369 | ~6.346 |
| area to the device area | | | | |

In one embodiment, one of the node dielectric layers 24 other than the first node dielectric layer 241 has a greater total outer vertical surface area than the first node dielectric layer 241. For example, the ratio of the total outer vertical surface area of a second node dielectric layer 242 to the total outer vertical surface area of the first node dielectric layer 241 can be greater than 1.0 for the second, third, and fourth configurations. Likewise, the ratio of the total outer vertical surface area of a third node dielectric layer 243 to the total outer vertical surface area of the first node dielectric layer 241 can be greater than 1.0 for the second, third, and fourth configurations; and the ratio of the total outer vertical surface area of a fourth node dielectric layer 244 to the total outer vertical surface area of the first node dielectric layer 241 can be greater than 1.0 for the second, third, and fourth configurations.

In one embodiment, at least one of the node dielectric layers 24 has a value less than 1.0 for a ratio of a total horizontal bottom surface area to a total area of outer vertical surfaces. In one embodiment, one of the node dielectric layers 24 has a value in a range from 0.2 to 1.0 for a ratio of a total horizontal bottom surface area to a total area of outer vertical surfaces. In Table 1, each of the node dielectric layers 24 has a value in a range from 0.2 to 1.0 for a ratio of a total horizontal bottom surface area to a total area of outer vertical surfaces. In some embodiments, a node dielectric layer 24 that is not the first node dielectric layer 241 and is not the topmost node dielectric layer 24 may have a minimum value for the ratio of a total horizontal bottom surface area to a total area of outer vertical surfaces.

In one embodiment, a ratio of a horizontal bottom surface area to a total outer vertical surface area is greater than 0.5 for at least one node dielectric layer 24 such as the first node dielectric layer 241. In one embodiment, a ratio of a horizontal bottom surface area to a total outer vertical surface area is greater than 0.5 for at least one node dielectric layer 24 such as a topmost node dielectric layer 24.

It is noted that any of the numerical values in Table 1 may be employed as a basis for defining a value or a range of values for any of the geometrical parameters in Table 1 despite the numbers in Table 1 being based on a specific exemplary geometry.

Table 2 below illustrates examples of the various geometrical parameters for four illustrative examples for the in-trench capacitor material assembly (21, 22, 24) for a first exemplary case in which all wall-to-wall distances between each facing pair of sidewalls of the second trench 13 separated by a respective void are the same as five times the first depth d1. The four illustrative examples include a fifth exemplary configuration including a single square-shaped opening within the in-trench capacitor material assembly (21, 22, 24), a sixth exemplary configuration including a 10×10 rectangular array of square-shaped openings within the in-trench capacitor material assembly (21, 22, 24), a seventh exemplary configuration including a 100×100 rectangular array of square-shaped openings within the in-trench capacitor material assembly (21, 22, 24), and an eighth exemplary configuration including a 1,000×1,000 rectangular array of square-shaped openings within the in-trench capacitor material assembly (21, 22, 24).

For the purpose of illustration, each square-shaped opening has sidewalls with a length of the first depth d1 (i.e., the depth of the second trench). A pair of first sidewalls of each square-shaped opening is parallel to a first horizontal direction hd1 (which is a first direction of repetition for each array of multiple openings), and a pair of second sidewalls of each square-shaped opening is parallel to a second horizontal direction hd2 (which is a second direction of repetition for each array of multiple openings). All sidewalls of the second trench 13 are assumed to be vertical. The lateral distance between each neighboring pair of sidewalls of the second trench 13 that is laterally spaced from each other by a respective void is assumed to equal 5 times the first depth d1. The sum of the thickness of a node dielectric layer 24 and the thickness of an electrode layer (21 or 22) is set at 0.25 times the first depth d1 for the purpose of the calculation. It should be understood that these assumptions are for the purpose of estimating various estimations for the areas of the bottom surfaces of the horizontally-extending portions of each node dielectric layer 24, and for the total areas of all outer sidewall surfaces of each node dielectric layer 24. Thus, by adjusting the various dimensional parameters and the taper angles of the sidewalls of the second trench isolation structures, and/or by selecting different numbers for the total number of openings in the in-trench capacitor material assembly (21, 22, 24), different values can be generated for the various numbers shown in Table 2.

TABLE 2
Characteristic dimensions for exemplary configurations of the capacitor of the present disclosure

| | | a 10 × 10 | | |
|---|---|---|---|---|
| type of openings in an in- | a single | square | a 100 × 100 | a 1000 × 1000 |
| trench capacitor material | square | array of | square array | square array of |
| assembly | opening | openings | of openings | openings |
| total number of openings in a | 1 | 100 | 10,000 | 1,000,000 |
| plan view | | | | |
| depth of a capacitor trench | d1 | d1 | d1 | d1 |
| lateral distance between each | d1 | d1 | d1 | d1 |
| neighboring pair of sidewalls | | | | |
| length of outer sidewalls along | (10 × 1 + | (6 × 10 + | (6 × 100 + | (6 × 1000 + |
| a first horizontal direction hd1 | 1) × d1 = | 5) × d1 = | 5) × d1 = | 5) × d1 = |
| | 11 d1 | 65 d1 | 605 d1 | 6,005 d1 |
| length of outer sidewalls along | (10 × 1 + | (6 × 10 + | (6 × 100 + | (6 × 1000 + |
| a second horizontal direction | 1) × d1 = | 5) × d1 = | 5) × d1 = | 5) × d1 = |
| hd2 | 11 d1 | 65 d1 | 605 d1 | 6,005 d1 |
| total area enclosed by outer | 121 (d1)² | 4,225 (d1)² | 366,025 (d1)² | 36,060,025 (d1)² |
| sidewalls | | | | |
| length of each sidewall of each | d1 | d1 | d1 | d1 |
| opening | | | | |
| total area of all openings | (d1)² | 100 (d1)² | 10,000 (d1)² | 1,000,000 (d1)² |
| total bottom area of the trench | 120 (d1)² | 4,125 (d1)² | 356,025 (d1)² | 35,060,025 (d1)² |
| (=total area of a horizontal | | | | |
| surface of a first node | | | | |
| dielectric layer) | | | | |
| total area of outer sidewalls | 4 × 11 | 4 × 65 | 4 × 605 | 4 × 6,005 |
| | d1 × d1 = | d1 × d1 = | d1 × d1 = | d1 × d1 |
| | 44 (d1)2 | 260 (d1)2 | 2,420 (d1)2 | =24,020 (d1)² |
| total area of sidewalls around | 1 × 4 × | 100 × 4 × | 10,000 × 4 × | 1,000,000 × 4 × |
| openings | d1 × d1 = | d1 × d1 = | d1 × d1 = | d1 × d1 = |
| | 4 (d1)² | 400 (d1)² | 40,000 (d1)² | 4,000,000 (d1)² |
| total area of all types of | 48 (d1)² | 660 (d1)² | 42,420 (d1)² | 4,024,020 (d1)² |
| sidewalls of the trench (=total | | | | |
| area of vertical surfaces of a | | | | |
| first node dielectric layer) | | | | |
| sum of a thickness of a node | 0.25 d1 | 0.25 d1 | 0.25 d1 | 0.25 d1 |
| dielectric layer and a thickness | | | | |
| of a primary or complementary | | | | |
| electrode layer | | | | |
| total area of a horizontal | (10.5 × | (64.5 × | (604.5 × | (6,004.5 × |
| bottom surface of a second | 10.5 − | 64.5 − | 604.5 − | 6,004.5 − |
| node dielectric layer | 1.5 × 1.5) × | 100 × 1.5 × | 10,00 × 1.5 × | 1,000,000 × |
| | (d1)² = 108 | 1.5) × (d1)² = | 1.5) × (d1)² = | 1.5 × 1.5) × |
| | (d1)² | 3,935.25 (d1)² | 342,920.25 (d1)² | (d1)² = |
| | | | | 33,804,020.25 (d1)² |
| total area of a horizontal | (10 × 10 − | (64 × 64 − | (604 × 604 − | (6,004 × 6,004 − |
| bottom surface of a third node | 2 × 2) × | 100 × 2 × | 10,00 × 2 × | 1,000,000 × 2 × |
| dielectric layer | (d1)² = | 2) × (d1)² = | 2) × (d1)² = | 2) × (d1)² = |
| | 96 (d1)² | 3,696 (d1)² | 324,816 (d1)² | 32,048,016 (d1)² |
| total area of a horizontal | (9.5 × 9.5 − | (63.5 × | (603.5 × | (6,003.5 × |
| bottom surface of a third node | 2.5 × 2.5) × | 63.5 − 100 × | 603.5 − | 6,003.5 − |
| dielectric layer | (d1)² = | 2.5 × 2.5) × | 10,00 × 2.5 × | 1,000,000 × 2.5 × |
| | 84 (d1)² | (d1)² = | 2.5) × (d1)² = | 2.5) × (d1)² = |
| | | 3,407.25 (d1)² | 301,712.25 (d1)² | 29,792,012.25 (d1)² |
| total area of outer vertical | (4 × 10.5 × | (4 × 64.5 × | (4 × 604.5 × | (4 × 6,004.5 × |
| surfaces of a second node | 0.75 + 4 × | 0.75 + 100 × | 0.75 + | 0.75 + |
| dielectric layer | 1.5 × 0.75) | 4 × 1.5 × | 10,000 × 4 × | 1,000,000 × 4 × |
| | (d1)² = | 0.75) | 1.25 × 0.75) | 1.25 × 0.75) |
| | 36 (d1)² | (d1)² = 643.5 | (d1)² = | (d1)² = |
| | | (d1)² | 46,813.5 (d1)² | 4,518,013.5 (d1)² |
| total area of outer vertical | (4 × 10 × | (4 × 64 × | (4 × 604 × | (4 × 6,004 × |
| surfaces of a third node | 0.5 + 4 × | 0.5 + 100 × | 0.5 + 10,000 × | 0.5 + 1,000,000 × |
| dielectric layer | 2.0 × 0.5) | 4 × 2 × | 4 × 2 × 0.5) | 4 × 2 × 0.5) |
| | (d1)² = | 0.5) (d1)² = | (d1)² = | (d1)² = |
| | 24 (d1)² | 528 (d1)² | 41,208 (d1)² | 4,012,008 (d1)² |
| total area of outer vertical | (4 × 9.5 × | (4 × 63.5 × | (4 × 603.5 × | (4 × 6,003.5 × |
| surfaces of a fourth node | 0.25 + 4 × | 0.25 + 100 × | 0.25 + | 0.25 + |
| dielectric layer | 2.5 × 0.25) | 4 × 2.5 × | 10,000 × 4 × | 1,000,000 × 4 × |
| | (d1)² = | 0.25) (d1)² = | 2.5 × 0.25) | 2.5 × 0.25) |
| | 12 (d1)² | 313.5 (d1)² | (d1)² = | (d1)² = |
| | | | 25,603.5 (d1)² | 2,506,003.5 (d1)² |
| the ratio of a horizontal bottom | 1.0 | 1.0 | 1.0 | 1.0 |
| surface area of a first node | | | | |
| dielectric layer to the | | | | |
| horizontal bottom surface area | | | | |
| of the first node dielectric layer | | | | |
| the ratio of a horizontal bottom | 0.9 | 0.954 | ~0.963 | ~0.964 |
| surface area of a second node | | | | |
| dielectric layer to the | | | | |
| horizontal bottom surface area | | | | |
| of the first node dielectric layer | | | | |
| the ratio of a horizontal bottom | 0.8 | 0.896 | ~0.912 | ~0.914 |
| surface area of a third node | | | | |
| dielectric layer to the | | | | |
| horizontal bottom surface area | | | | |
| of the first node dielectric layer | | | | |
| the ratio of a horizontal bottom | 0.7 | 0.826 | ~0.847 | ~0.849 |
| surface area of a fourth node | | | | |
| dielectric layer to the | | | | |
| horizontal bottom surface area | | | | |
| of the first node dielectric layer | | | | |
| the ratio of the total outer | 1.0 | 1.0 | 1.0 | 1.0 |
| vertical surface area of a first | | | | |
| node dielectric layer to the | | | | |
| total outer vertical surface area | | | | |
| of the first node dielectric layer | | | | |
| the ratio of the total outer | 0.75 | 0.975 | ~1.103 | ~1.122 |
| vertical surface area of a | | | | |
| second node dielectric layer to | | | | |
| the total outer vertical surface | | | | |
| area of the first node dielectric | | | | |
| layer | | | | |
| the ratio of the total outer | 0.5 | 0.8 | ~0.971 | ~0.997 |
| vertical surface area of a third | | | | |
| node dielectric layer to the | | | | |
| total outer vertical surface area | | | | |
| of the first node dielectric layer | | | | |
| the ratio of the total outer | 0.25 | 0.475 | ~0.603 | ~0.622 |
| vertical surface area of a fourth | | | | |
| node dielectric layer to the | | | | |
| total outer vertical surface area | | | | |
| of the first node dielectric layer | | | | |
| the ratio of a horizontal bottom | 2.5 | 6.25 | ~8.392 | ~8.712 |
| surface area to total outer | | | | |
| vertical surface area for a first | | | | |
| node dielectric layer | | | | |
| the ratio of a horizontal bottom | 3 | ~6.115 | ~7.325 | ~7.482 |
| surface area to total outer | | | | |
| vertical surface area for a | | | | |
| second node dielectric layer | | | | |
| the ratio of a horizontal bottom | 4 | 7 | ~7.882 | ~7.988 |
| surface area to total outer | | | | |
| vertical surface area for a third | | | | |
| node dielectric layer | | | | |
| the ratio of a horizontal bottom | 7 | ~10.868 | ~11.784 | ~11.888 |
| surface area to total outer | | | | |
| vertical surface area for a | | | | |
| fourth node dielectric layer | | | | |
| total node dielectric area = the | 528 (d1)² | ~17,308 (d1)² | ~1,481,518 (d1)² | ~145,764,118 (d1)² |
| sum of all horizontal bottom | | | | |
| surface areas and all outer | | | | |
| vertical surface areas for all 4 | | | | |
| node dielectrics | | | | |
| device area (as defined by the | 121 (d1)² | 4,225 (d1)² | 366,025 (d1)² | 36,060,025 (d1)² |
| outer periphery of the second | | | | |
| trench) | | | | |
| the ratio of the total node | ~4.363 | ~4.096 | ~4.047 | ~4.042 |
| dielectric area to the device | | | | |
| area | | | | |

In one embodiment, one of the node dielectric layers 24 other than the first node dielectric layer 241 has a greater total outer vertical surface area than the first node dielectric layer 241. For example, the ratio of the total outer vertical surface area of a second node dielectric layer 242 to the total outer vertical surface area of the first node dielectric layer 241 can be greater than 1.0 for the seventh and eighth configurations.

In one embodiment, a node dielectric layer 24 that is not the first node dielectric layer 241 and is not the topmost node dielectric layer 24 (such as the fourth node dielectric layer 244) may have a minimum value among the node dielectric layers 24 for the ratio of a horizontal bottom surface area to a total outer vertical surface area. For example, the minimum for the ratio of a horizontal bottom surface area to a total outer vertical surface area occurs for the second node dielectric layer 242 in the sixth, seventh, and eighth configuration.

In one embodiment, at least one of the node dielectric layers 24 has a value greater than 1.0 for a ratio of a total horizontal bottom surface area to a total area of outer vertical surfaces. In one embodiment, at least one of the node dielectric layers 24 has a value in a range from 1.0 to 20, such as from 2.0 to 12, for a ratio of a total horizontal bottom surface area to a total area of outer vertical surfaces. In Table 2, each of the node dielectric layers 24 has a value in a range from 2.5 to 12 for a ratio of a total horizontal bottom surface area to a total area of outer vertical surfaces. In some embodiments, a node dielectric layer 24 that is not the first node dielectric layer 241 and is not the topmost node dielectric layer 24 may have a minimum value for the ratio of a total horizontal bottom surface area to a total area of outer vertical surfaces (which is the case for the sixth, seventh, and eighth configuration).

In one embodiment, a ratio of a horizontal bottom surface area to a total outer vertical surface area is greater than 1.0, and/or is greater than 2.0, and/or is greater than 4.0, for at least one node dielectric layer 24 such as the first node dielectric layer 241. It is noted that any of the numerical values in Table 2 may be employed as a basis for defining a value or a range of values for any of the geometrical parameters in Table 2 despite the numbers in Table 2 being based on a specific exemplary geometry.

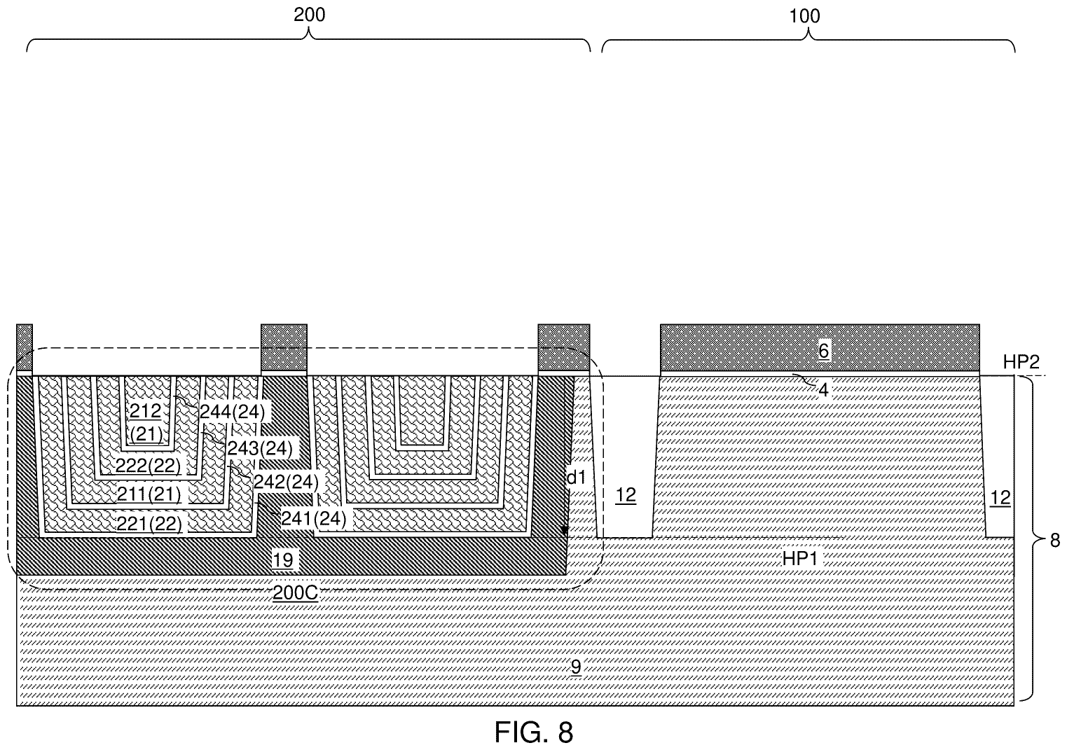

Referring to FIG. 8, a recess etch process may be performed to vertically recess the trench isolation structure 12 in the transistor region 100. The recess etch process may comprise a reactive ion etch process and/or a wet etch process. The top surface of the trench isolation structure 12 may be formed at, or around, the second horizontal plane HP2. Alternatively, the trench isolation structure 12 in the transistor region 100 may be recessed together with the in-trench capacitor material assembly (21, 22, 24) during the recess etch step shown in FIGS. 7A and 7B. In this case, the separate recess etch step shown in FIG. 8 may be omitted.

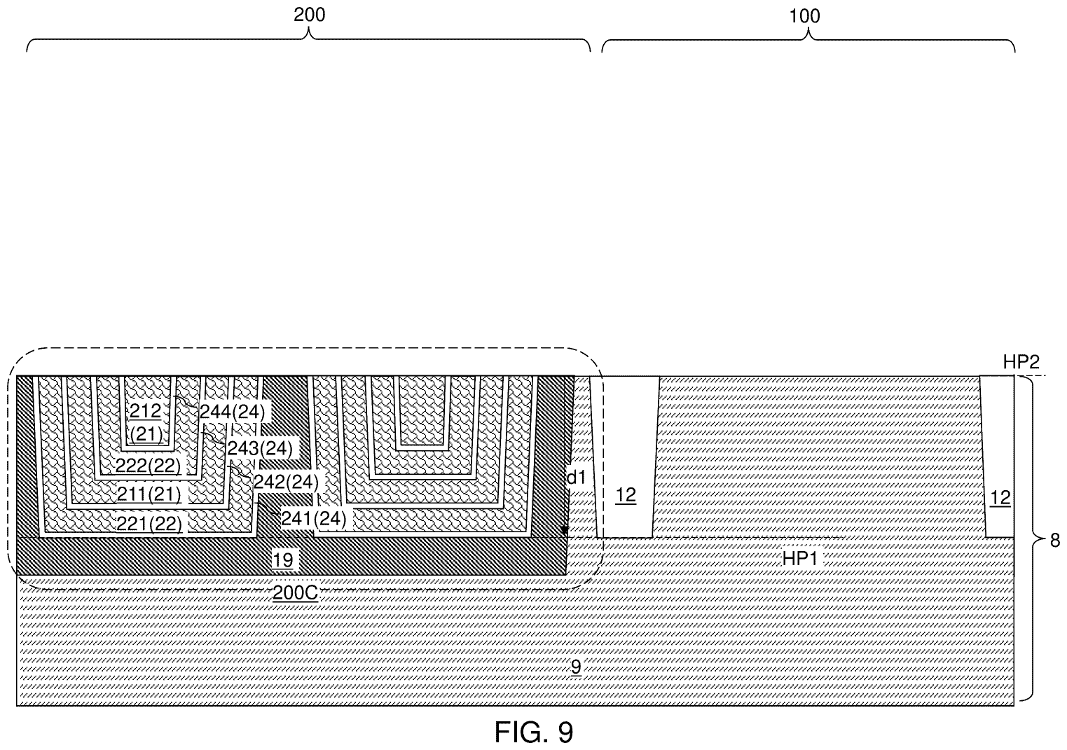

Referring to FIG. 9, the hard mask layer 6 can be removed selective to the materials of the substrate semiconductor layer 9, the doped substrate electrode layer 19, the in-trench capacitor material assembly (21, 22, 24), and the trench isolation structure 12. For example, if the hard mask layer 6 comprises silicon nitride, a wet etch process employing hot phosphoric acid may be performed.

Subsequently, the pad dielectric layer 4 (if present) can be removed selective to the materials of the substrate semiconductor layer 9, the doped substrate electrode layer 19, and the in-trench capacitor material assembly (21, 22, 24). For example, if the pad dielectric layer 4 comprises silicon oxide, a wet etch process employing dilute hydrofluoric acid may be performed to remove the pad dielectric layer 4.

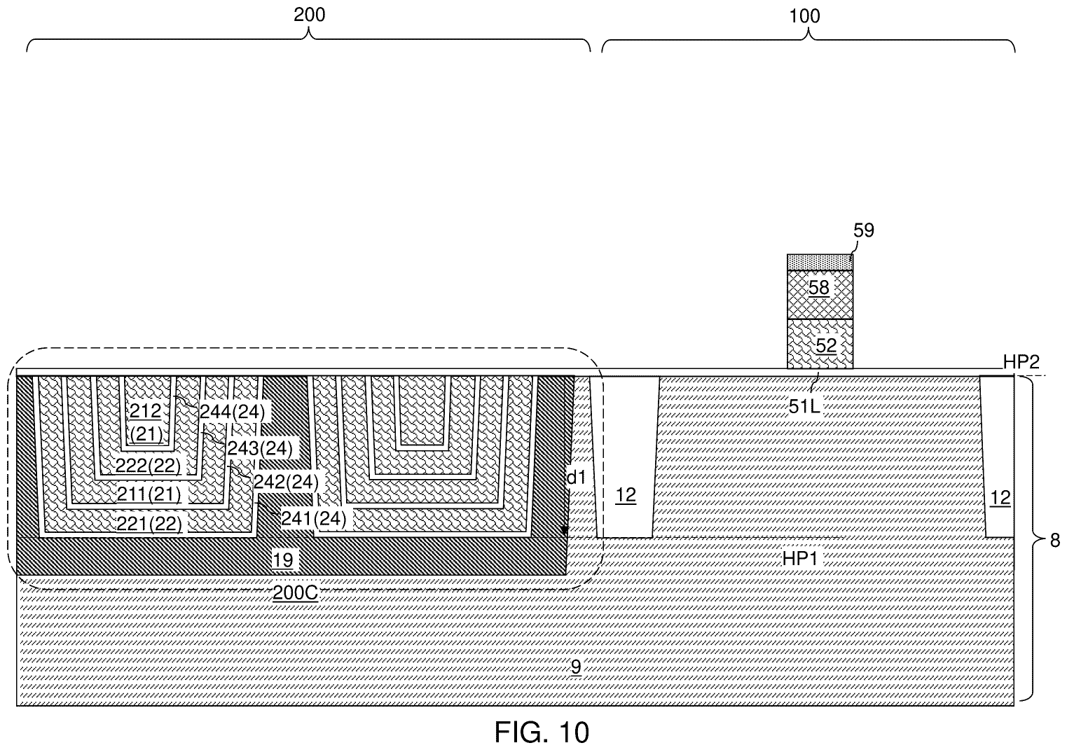

Referring to FIG. 10, a gate dielectric material layer 51L can be formed over the top surfaces of the semiconductor substrate 8, the in-trench capacitor material assembly (21, 22, 24), and the trench isolation structure 12. The gate dielectric material layer 51L may comprise any suitable gate dielectric, such as silicon oxide or silicon oxynitride. The thickness of the gate dielectric material layer 51L may be in a range from 2 nm to 12 nm, such as from 5 nm to 10 nm, although lesser and greater thicknesses may also be employed.

At least one gate electrode material layer and a gate cap dielectric layer can be deposited over the gate dielectric material layer 51L. A photoresist layer can be applied over the gate cap dielectric layer, and can be lithographically patterned into a pattern of a gate electrode to be subsequently performed. An anisotropic etch process can be performed to etch unmasked portions of the gate cap dielectric layer and the at least one gate electrode material layer. A remaining portion of the gate cap dielectric layer after the anisotropic etch process comprises a gate cap dielectric 59. A remaining portion of the at least one gate electrode material layer after the anisotropic etch process comprises a gate electrode (52, 58). If the at least one gate electrode material layer comprises a vertical stack of a semiconductor gate electrode material layer and a metallic gate electrode material layer (e.g., conductive metal nitride or metal silicide), the gate electrode (52, 58) may comprise a vertical stack of a semiconductor gate electrode 52 and a metallic gate electrode 58. The photoresist layer can be subsequently removed, for example, by ashing.

In one embodiment, the semiconductor gate electrode 52 comprises a heavily doped polysilicon or amorphous silicon doped with n-type (e.g., phosphorus) dopants at a concentration in a range from 5×10¹⁹/cm³ to 2×10²¹/cm³, although lesser and greater atomic concentrations may also be employed. The thickness of the semiconductor gate electrode 52 may be in a range from 30 nm to 100 nm, such as from 50 nm to 70 nm, although lesser and greater thicknesses may also be employed. The metallic gate electrode 58 comprises a conductive metallic nitride material and/or a transition metal or metal silicide (such as Ti, Ta, W, Mo, Ru, etc. or silicides thereof).

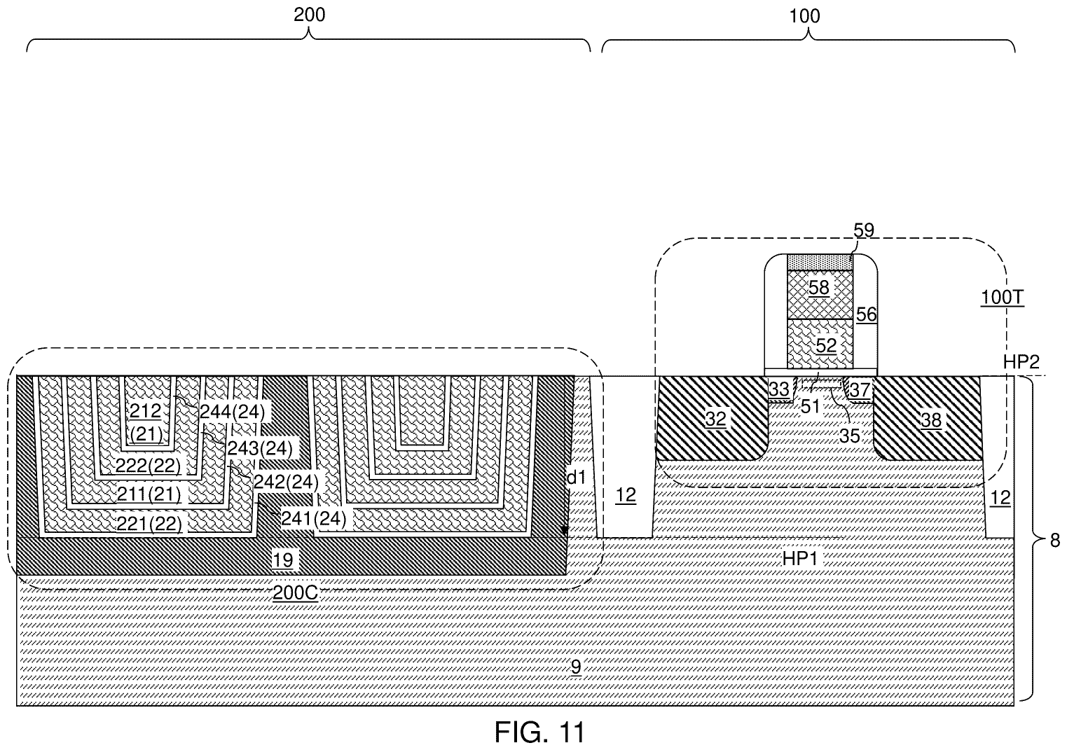

Referring to FIG. 11, a field effect transistor 100T can be formed in the transistor region 100. For example, a source extension region 33 and a drain extension region 37 can be formed by performing a source/drain extension ion implantation process. A dielectric gate spacer 56 can be formed around the gate electrode (52, 58) by conformally depositing and anisotropically etching at least one dielectric gate spacer material, which may comprise silicon oxide and/or silicon nitride. A deep source region 32 and a deep drain region 38 can be formed by performing a source/drain ion implantation process. A semiconductor channel region 35 is located in the substrate semiconductor layer 9 between the extension regions (33, 37).

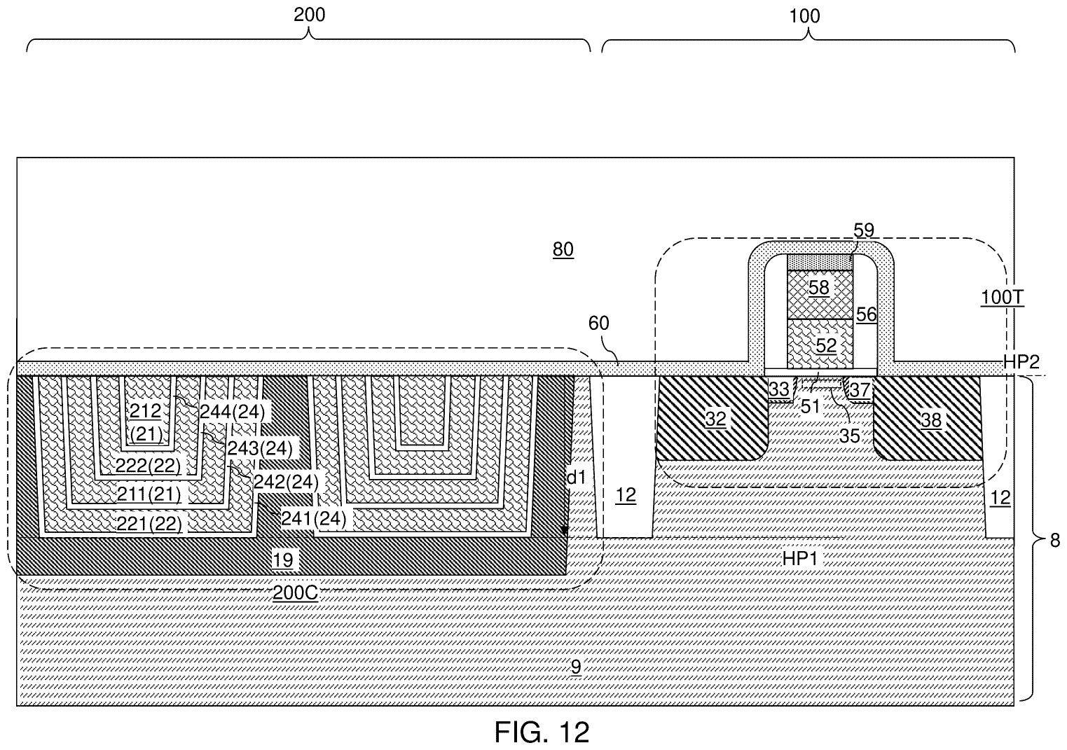

Referring to FIG. 12, an optional dielectric capping layer 60 can be formed over the field effect transistor 100T and the capacitor 200C. The dielectric capping layer 60 comprises a dielectric diffusion barrier material such as silicon nitride or silicon carbonitride. The thickness of the dielectric capping layer 60 may be in a range from 10 nm to 50 nm, although lesser and greater thicknesses may also be employed. In one embodiment, the dielectric capping layer 60 may contact top surfaces of all layers within the in-trench capacitor material assembly (21, 22, 24). A contact-level dielectric layer 80, such as a silicon oxide layer, can be formed over the dielectric capping layer 60. The top surface of the contact-level dielectric layer 80 may be planarized as needed, for example, by performing a chemical mechanical polishing process.

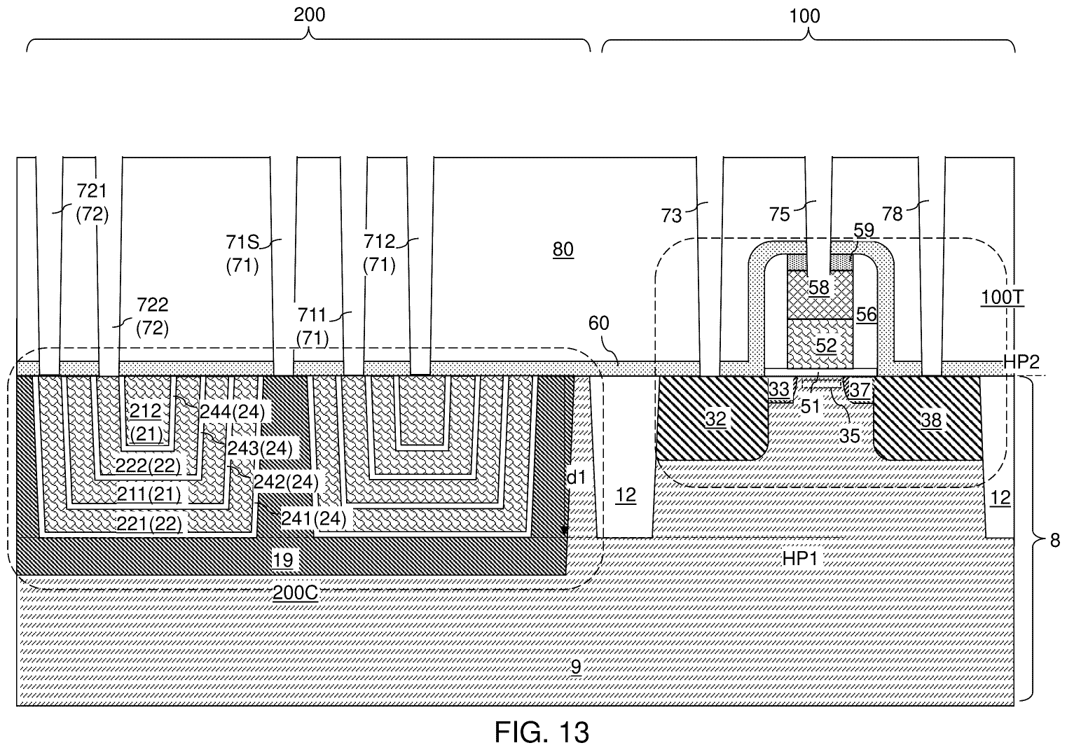

Referring to FIG. 13, contact via cavities (73, 75, 78, 71, 72) can be formed through the contact-level dielectric layer 80. The contact via cavities (73, 75, 78, 71, 72) may comprise a source contact via cavity 73 that is formed on the deep source region 32, a gate contact via cavity 75 that is formed on the gate electrode (52, 58), a drain contact via cavity 78 that is formed on the deep drain region 38, primary electrode contact via cavities 71 that are formed on the doped substrate electrode layer 19 and the primary electrode layers 21, and complementary electrode contact via cavities 72 that are formed on the complementary electrode layers 22. The primary electrode contact via cavities 71 may comprise a substrate primary electrode contact via cavity 71S that is formed on the doped substrate electrode layer 19, a first primary electrode contact via cavity 711 that is formed on the first primary electrode layer 211, a second primary electrode contact via cavity 712 that is formed on the second primary electrode layer 212, etc. The complementary electrode contact via cavities 72 may comprise a first complementary electrode contact via cavity 721 that is formed on the first complementary electrode layer 221, a second complementary electrode contact via cavity 722 that is formed on the second complementary electrode layer 222, etc.

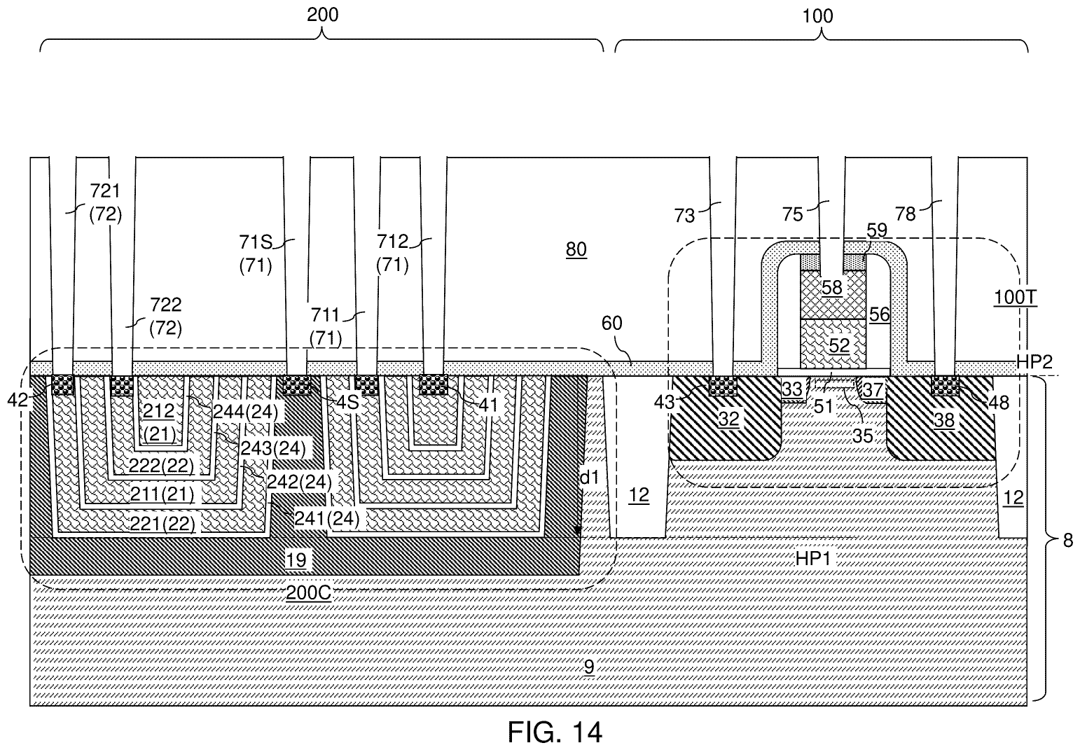

Referring to FIG. 14, various optional metal-semiconductor alloy regions (43, 48, 4S, 41, 42), such as metal silicide regions, can optionally be formed on physically exposed surfaces of semiconductor material portions, which include physically exposed surfaces of the deep source region 32, the deep drain region 38, the doped substrate electrode layer 19, the primary electrode layers 21 (if the primary electrode layers 21 include a doped semiconductor material), and the complementary electrode layers 22 (if the complementary electrode layers 22 include a doped semiconductor material). Generally, a metal layer that reacts with the semiconductor materials of the deep source region 32, the deep drain region 38, the doped substrate electrode layer 19, the complementary electrode layers 22 (if the complementary electrode layers 22 include a doped semiconductor material), and the primary electrode layers 21 (if the primary electrode layers 21 include a doped semiconductor material) can be deposited at the bottom of the contact via cavities (73, 75, 78, 71, 72). The metal may comprise any silicide forming metal, such as Ti, Pd, Ni, Co, W, Ta, Mo, etc.

An anneal process can be performed to induce formation of metal-semiconductor alloy material portions (e.g., metal silicide portions), such as silicide portions of a metal selected from Ti, Pd, Ni, Co, W, Ta and/or Mo. Unreacted portions of the metal layer can be removed by performing a wet etch process that etches the remaining portion of the metal layer selective to the metal-semiconductor materials. Various metal-semiconductor alloy regions (43, 48, 4S, 41, 42) remain after selective removal of the unreacted portions of the metal layer. The various metal-semiconductor alloy regions (43, 48, 4S, 41, 42) may comprise a source metal-semiconductor alloy region 43, a drain metal-semiconductor alloy region 48, a substrate electrode metal-semiconductor alloy region 4S, primary electrode metal-semiconductor alloy regions 41 (if the primary electrode layers 21 comprise a doped semiconductor material), and complementary electrode metal-semiconductor alloy regions 42 (if the complementary electrode layers 22 comprise a doped semiconductor material). Alternatively, the metal-semiconductor alloy regions (42, 48, 142) may be omitted.

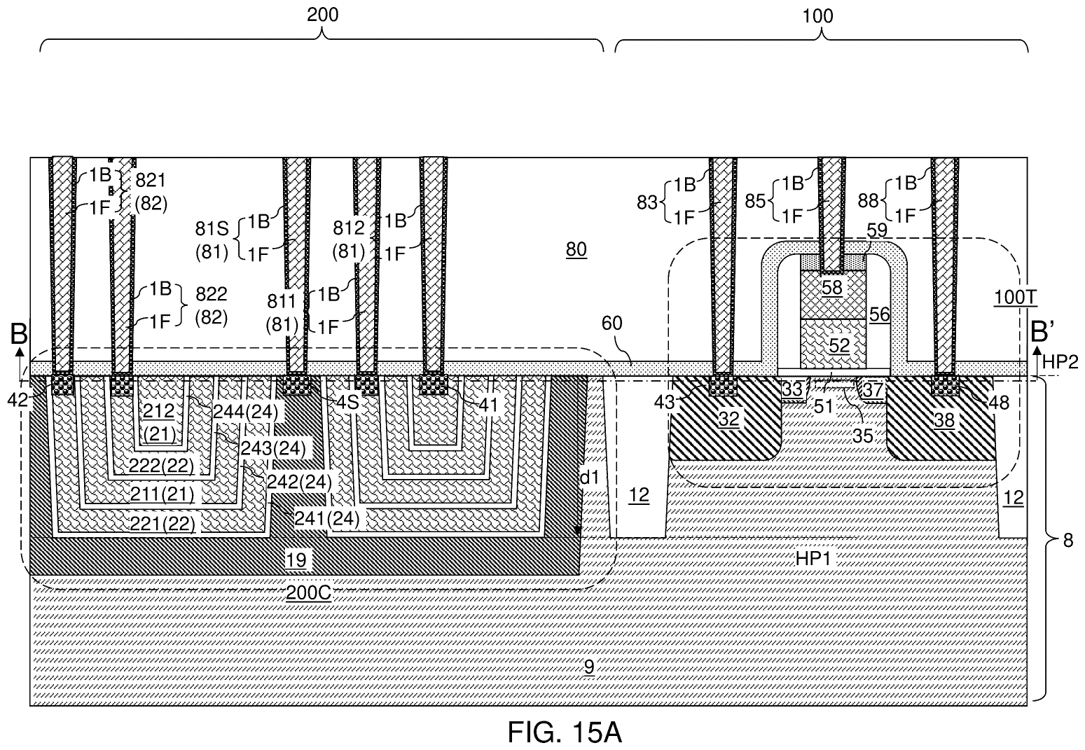

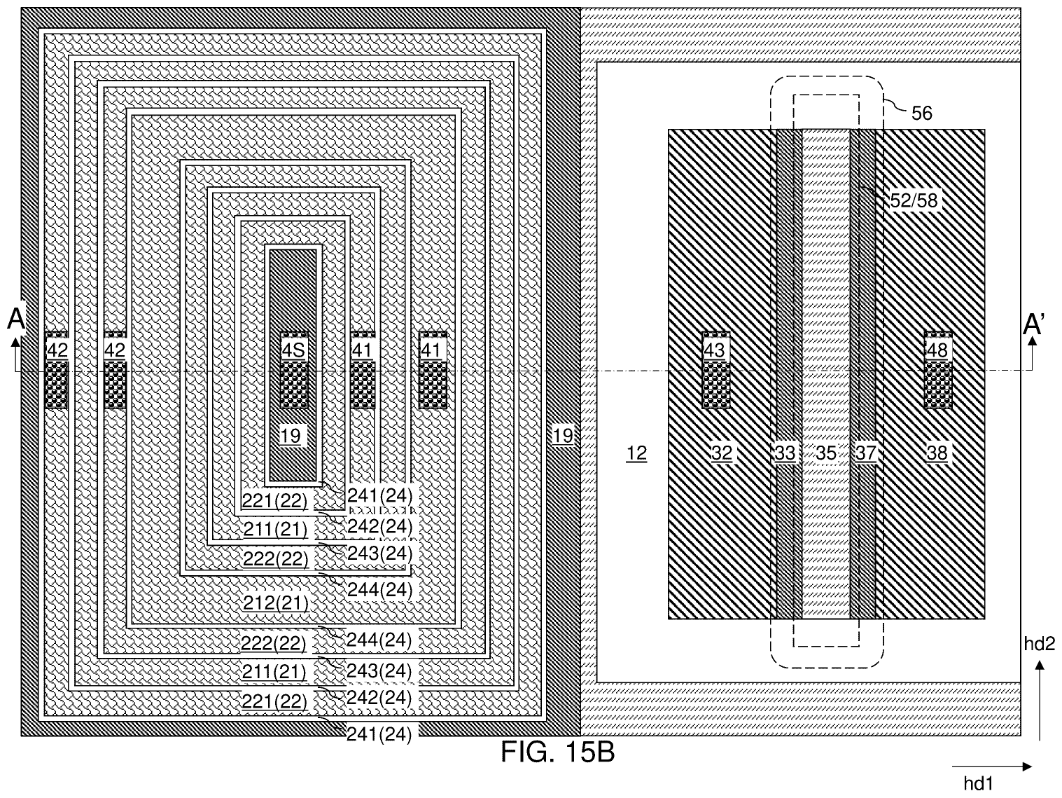

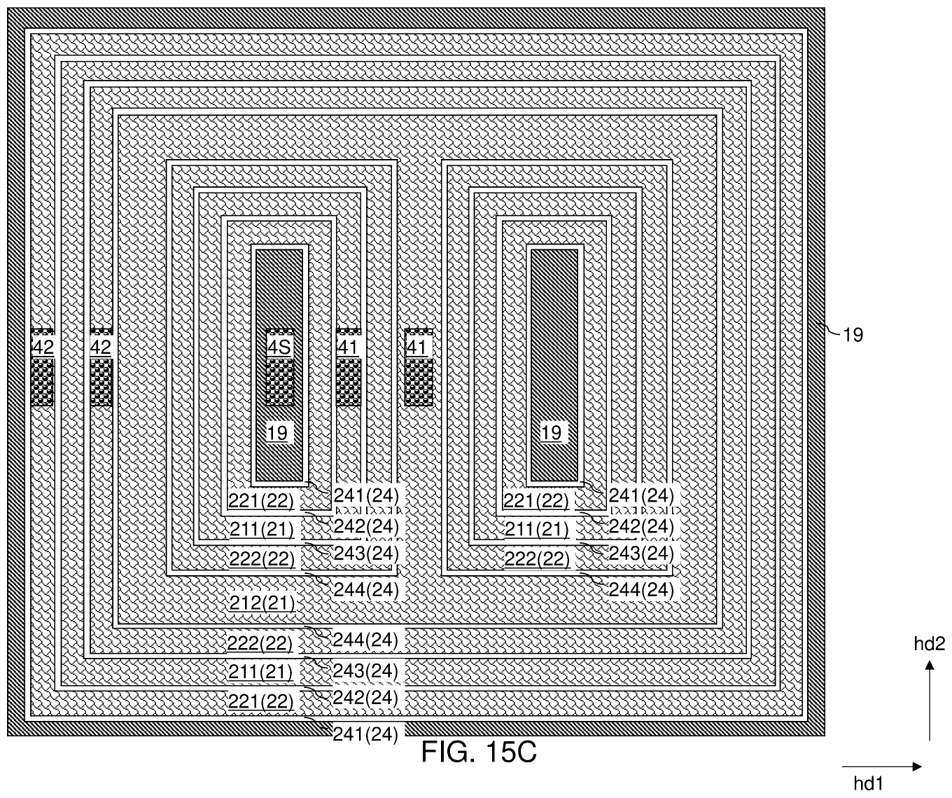

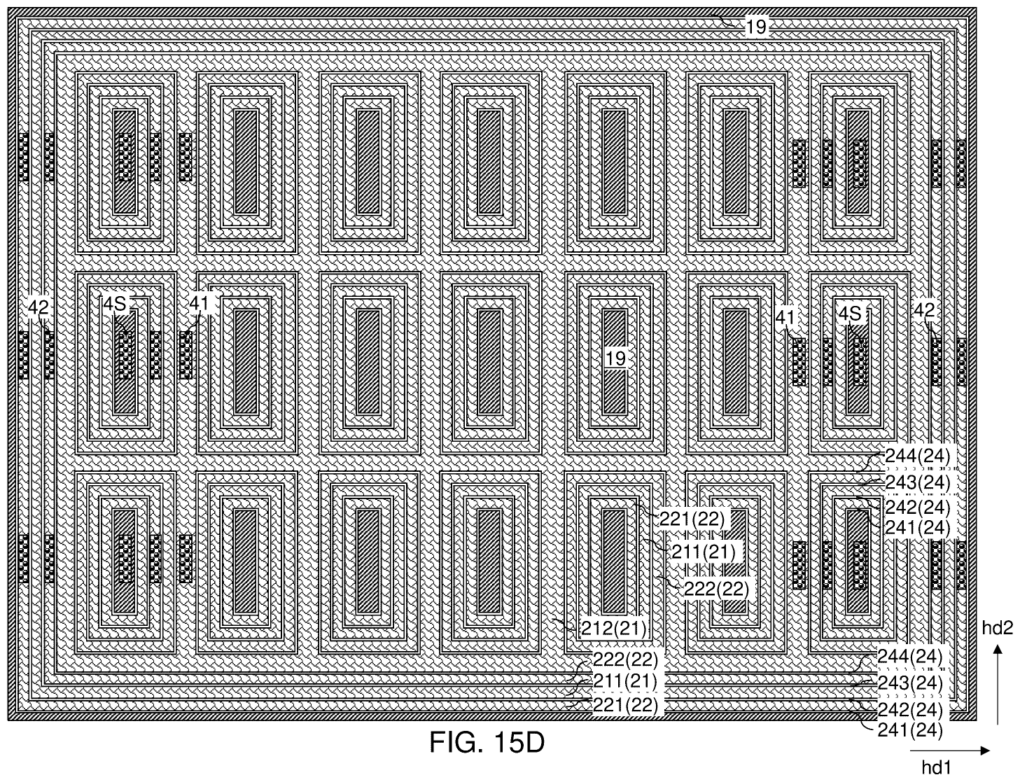

Referring to FIGS. 15A-15D, various contact via structures (83, 85, 88, 81, 82) can be formed in the contact via cavities (73, 75, 78, 71, 72). For example, a source contact via structure 83 can be formed in the source contact via cavity 73, a gate contact via structure 85 can be formed in the gate contact via cavity 75, a drain contact via structure 88 can be formed in the drain contact via cavity 78, primary electrode contact via structures 81 can be formed in the primary electrode contact via cavities 71, and complementary electrode contact via structures 82 can be formed in the complementary electrode contact via cavities 72. The primary electrode contact via structures 81 may comprise a substrate primary electrode contact via structure 81S that is electrically connected to the doped substrate electrode layer 19, a first primary electrode contact via structure 811 that is electrically connected to the first primary electrode layer 211, a second primary electrode contact via structure 812 that is electrically connected to the second primary electrode layer 212, etc. The complementary electrode contact via structures 82 may comprise a first complementary electrode contact via structure 821 that is electrically connected to the first complementary electrode layer 221, a second complementary electrode contact via structure 822 that is electrically connected to the second complementary electrode layer 222, etc. Each of the contact via structures (83, 85, 88, 81, 82) may comprise a respective combination of a via-level metallic barrier liner 1B including a contact-level metallic barrier material (such as TiN, TaN, MON, and/or WN) and a via-level metal fill material portion 1F including a contact-level metallic fill material (such as W, Ti, Ta, Mo, Ru, etc.).

In one embodiment, the doped substrate electrode layer 19 and the at least one primary electrode layer 21 may be electrically connected to each other through a first subset of metal interconnect structures that overlie the semiconductor substrate 8. The first subset of the metal interconnect structures comprises at least two metal via structures and a metal line. For example, the first subset of the metal interconnect structures may comprise primary electrode contact via structures 81 that are electrically connected to each other by a primary-electrode-connection metal line (not shown) that overlies the primary electrode contact via structures 81. In an alternative embodiment, the doped substrate electrode layer 19 and the at least one primary electrode layer 21 are not electrically connected to each other.

In one embodiment, the at least one complementary electrode layer 22 may comprise a plurality of complementary electrode layers 22 that are electrically connected to each other through a second set of the metal interconnect structures. For example, the second subset of the metal interconnect structures may comprise complementary electrode contact via structures 82 and a complementary-electrode-connection metal line (not shown) that overlies the complementary electrode contact via structures 82. In an alternative embodiment, the plurality of complementary electrode layers 22 are not electrically connected to each other.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure comprising:
a semiconductor substrate including a first trench and a second trench in an upper portion thereof;
a trench isolation structure comprising a dielectric fill material and located in the first trench; and
a capacitor which comprises:
a doped substrate electrode layer located within the semiconductor substrate and underlying and laterally surrounding the second trench; and
an in-trench capacitor material assembly located within the second trench and comprising at least one primary electrode layer, at least one complementary electrode layer, and node dielectric layers, wherein each neighboring pair among the doped substrate electrode layer, the at least one primary electrode layer, and the at least one complementary electrode layer is spaced from each other by a respective one of the node dielectric layers.

2. The semiconductor structure of claim 1, wherein a bottom surface of the second trench is located within a first horizontal plane that is located at a depth that is in a range from 0.7 times a depth of a bottom surface of the first trench to 1.0 times the depth of the bottom surface of the first trench.

3. The semiconductor structure of claim 2, wherein a top surface of the doped substrate electrode layer is located within a second horizontal plane including a top surface of the semiconductor substrate.

4. The semiconductor structure of claim 1, wherein:
the in-trench capacitor material assembly comprises at least one opening therethrough in a plan view; and
each of the at least one opening is filled with a respective sub-portion of the doped substrate electrode layer.

5. The semiconductor structure of claim 4, wherein each sub-portion of the doped substrate electrode layer located within a respective opening in the in-trench capacitor material assembly comprises a respective top surface segment that is located within a horizontal plane including a top surface of the semiconductor substrate.

6. The semiconductor structure of claim 4, wherein the at least one opening comprises a plurality of openings.

7. The semiconductor structure of claim 4, wherein the at least one opening comprises a two-dimensional array of opening arranged along a first horizontal direction and along a second horizontal direction that is different from the first horizontal direction.

8. The semiconductor structure of claim 1, wherein:
the node dielectric layers comprise a first node dielectric layer in contact with the doped substrate electrode layer;
the at least one complementary electrode layer comprises a first complementary electrode layer in contact with the first node dielectric layer;
the node dielectric layers further comprise a second node dielectric layer in contact with the first complementary electrode layer; and
the at least one primary electrode layer comprises a first primary electrode layer in contact with the second node dielectric layer.

9. The semiconductor structure of claim 8, wherein one of the node dielectric layers other than the first node dielectric layer has a greater total outer vertical surface area than the first node dielectric layer.

10. The semiconductor structure of claim 8, wherein one of the node dielectric layers has a value in a range from 0.2 to 1.0 for a ratio of a total horizontal bottom surface area to a total area of outer vertical surfaces.

11. The semiconductor structure of claim 8, wherein a ratio of a horizontal bottom surface area to a total outer vertical surface area is greater than 0.5 for the first node dielectric layer.

12. The semiconductor structure of claim 8, wherein:
the node dielectric layers further comprise a third node dielectric layer in contact with the first primary electrode layer; and
the at least one complementary electrode layer further comprises a second complementary electrode layer in contact with the third node dielectric layer.

13. The semiconductor structure of claim 1, wherein:
the doped substrate electrode layer and the at least one primary electrode layer are electrically connected to each other through a first subset of metal interconnect structures that overlie the semiconductor substrate; and
the at least one complementary electrode layer comprises a plurality of complementary electrode layers that are electrically connected to each other through a second set of the metal interconnect structures.

14. The semiconductor structure of claim 1, further comprising:
a substrate primary electrode contact via structure that is electrically connected to the doped substrate electrode layer;
at least one primary electrode contact via structure that is electrically connected to the at least one first primary electrode layer; and
at least one complementary electrode contact via structure that is electrically connected to the at least one first complementary electrode layer.

15. The semiconductor structure of claim 1, further comprising a field effect transistor located on the substrate and surrounded by the trench isolation structure.

16. A method of forming a semiconductor structure, comprising:
forming a first trench and a second trench in an upper portion of a semiconductor substrate by performing an etch process that simultaneously removes a first portion and a second portion of the semiconductor substrate;
forming a trench isolation structure comprising a first portion of a dielectric fill material in the first trench and forming a void within the second trench; and
forming in-trench capacitor material assembly within the second trench, the in-trench capacitor material assembly comprising a doped substrate electrode layer, at least one primary electrode layer, at least one complementary electrode layer, and node dielectric layers, wherein each neighboring pair among the doped substrate electrode layer, the at least one primary electrode layer, and the at least one complementary electrode layer is spaced from each other by a respective one of the node dielectric layers.

17. The method of claim 16, further comprising:
depositing the dielectric fill material in the first trench and in the second trench simultaneously; and
removing a second portion of the dielectric fill material that is deposited in the second trench without removing the first portion of the dielectric fill material from inside the second trench to form the void within the second trench.

18. The method of claim 16, wherein the doped substrate electrode layer underlies and laterally surrounds the second trench.

19. The method of claim 16, wherein an area of the second trench includes at least one perforation therethrough in a plan view.

20. The method of claim 16, further comprising:
forming a patterned hard mask layer over the semiconductor substrate, wherein the etch process is performed employing the patterned hard mask layer as an etch mask for the etch process;
depositing and planarizing the dielectric fill material in the first trench and in the second trench employing the patterned hard mask layer as a planarization stopper layer;
removing a second portion of the dielectric fill material that is deposited in the second trench by performing an additional etch process that employs the patterned hard mask layer as an etch mask for the additional etch process; and
depositing and planarizing an alternating sequence of the node dielectric material layers and electrode material layers employing the patterned hard mask layer as a planarization stopper layer for a planarization process that removes portions of the alternating sequence at least from above a horizontal plane including a top surface of the patterned hard mask layer, wherein remaining portions of the alternating sequence comprise the in-trench capacitor material assembly.
